(19) United States
(12) Patent Application Publication
(10) Pub. No.: US 2010/0190036 A1
(43) Pub. Date: Jul. 29, 2010

(54) Systems and Methods for Surface Modification by Filtered Cathodic Vacuum Arc

(76) Inventors: Kyriakos Komvopoulos, Orinda, CA (US); Hanshen Zhang, Albany, CA (US); Charanjit Singh Bhatia, Berkeley, CA (US)

Correspondence Address: UC Berkeley - OTL;Bozicevic, Field & Francis LLP, 1900 University Avenue, Suite 200, East Palo Alto, CA, 94303, US

(21) Appl. No.: 12/695,039

(22) Filed: Jan. 27, 2010

Related U.S. Application Data
(60) Provisional application No. 61/147,697, filed on Jan. 27, 2009.

(51) Int. Cl. G11B 5/66; C23C 16/50; G11B 5/84

(52) U.S. Cl. 428/832; 427/569; 118/723 R

(57) ABSTRACT

Provided are filtered cathodic vacuum arc systems useful for modifying a surface of a substrate (e.g. depositing a thin film of a material onto a surface of a substrate and/or implanting a material into the near-surface region of a substrate). The systems are configured to stabilize a do arc discharge plasma from an arc source. Also provided are methods for modifying a surface of a substrate, which in some cases includes depositing a material onto a surface of a substrate, in some cases includes implanting a material into the near-surface region of a substrate, and in some cases includes both depositing a material onto a surface of a substrate and implanting a material into the near-surface region of a substrate using the subject cathodic arc systems. In addition, magnetic recording media produced by the subject systems and methods are provided.

### CROSS-REFERENCE TO RELATED APPLICATION

Pursuant to 35 U.S.C. §119(e), this application claims priority to the filing date of U.S. Provisional Patent Application Ser. No. 61/147,697, filed Jan. 27, 2009, which application is incorporated herein by reference in its entirety.

### INTRODUCTION

Fabrication of magnetic recording media, such as hard disks and magnetic recording heads, includes an outermost protective layer, typically an amorphous carbon (a-C) film, deposited onto the magnetic layer of the hard disk (or directly onto a ceramic magnetic recording head) before applying a molecularly thin lubricant layer by a spin-coating method. In view of continuing demands for even higher magnetic recording densities (e.g., 10 Tbit/in² or higher), the headspace above the media must be reduced. The space occupied by the a-C overcoat is a major obstacle in achieving magnetic recording densities on the order of 10 Tbit/in² or higher.

One type of material deposition protocol is cathodic arc deposition. In cathodic arc plasma deposition, a form of ion beam deposition, an electrical arc is generated between a cathode and an anode that causes ions from the cathode to be liberated and thereby produce an ion beam. The resultant ion beam, e.g., plasma of cathodic material ions, is then directed toward the substrate surface to deposit and/or chemically modify the substrate surface.

### SUMMARY

Provided are filtered cathodic vacuum arc systems useful for modifying a surface of a substrate (e.g. depositing a thin film of a material onto a surface of a substrate and/or implanting a material into the near-surface region of a substrate). The systems are configured to stabilize a dc arc discharge plasma from an arc source. Also provided are methods for modifying a surface of a substrate, which in some cases includes depositing a material onto a surface of a substrate, in some cases includes implanting a material into the near-surface region of a substrate, and in some cases includes both depositing a material onto a surface of a substrate and implanting a material into the near-surface region of a substrate using the subject cathodic arc systems. In addition, magnetic recording media produced by the subject systems and methods are provided.

### BRIEF DESCRIPTION OF THE FIGURES

FIG. 1(a) shows a schematic of a top view of a cathodic arc deposition system according to embodiments of the present disclosure. FIG. 1(b) shows a schematic of a side view of a cathodic arc deposition system according to embodiments of the present disclosure.

FIG. 2 shows a schematic of a cross section of the plasma-stabilizing mechanism during dc arc discharge according to embodiments of the present disclosure. The magnetic field lines produced by the cathode coil and the upstream coil are shown only at the left side of the coil cross section for clarity.

FIG. 3 shows carbon depth profiles simulated with the T-DYN code for 120 eV kinetic energy of carbon ions impinging perpendicular to a silicon substrate surface according to embodiments of the present disclosure.

FIG. 4(a) shows carbon depth profiles simulated with the T-DYN code for 20 eV to 320 eV kinetic energy of carbon ions impinging perpendicular to a silicon substrate surface and carbon ion fluence equal to 3.6×10¹⁶ ions/cm² corresponding to 0.4 min process times according to embodiments of the present disclosure. FIG. 4(b) shows carbon depth profiles simulated with the T-DYN code for 20 eV to 320 eV kinetic energy of carbon ions impinging perpendicular to a silicon substrate surface and carbon ion fluence equal to 1.8×10¹⁶ ions/cm² corresponding to 0.2 min process times according to embodiments of the present disclosure.

FIG. 5 shows XRR results for 0.2 min to 3 min process times, 120 eV carbon ion kinetic energy (e.g., −100 V bias voltage of 25 kHz frequency) and 1.48×10¹⁵ ions/cm²·s ion flux for an FCVA process on a silicon substrate according to embodiments of the present disclosure.

FIG. 6 shows C1s XPS spectrum of C1s core level peak for 170 eV carbon ion kinetic energy (e.g., −150 V bias voltage of 25 kHz frequency) and 0.4 min process time (e.g., 3.6×10¹⁶ ions/cm² ion fluence) for an FCVA process on a silicon substrate according to embodiments of the present disclosure. The spectrum was fitted by six Gaussian curves after inelastic background subtraction.

FIG. 7(a) shows binding energies of characteristic Gaussian fits of C1s core level peak for an FCVA process on a silicon substrate according to embodiments of the present disclosure. FIG. 7(b) shows fraction of carbon constituents of deconvoluted C1s core level peak vs. process time for 120 eV carbon ion kinetic energy (e.g., −100 V bias voltage of 25 kHz frequency) for an FCVA process on a silicon substrate according to embodiments of the present disclosure.

FIG. 8(a) shows carbon constituents of deconvoluted C1s core level peak vs. substrate bias voltage of 25 kHz frequency for 0.4 min process times corresponding to 3.6×10¹⁶ ions/cm² ion fluence for an FCVA process on a silicon substrate according to embodiments of the present disclosure. FIG. 8(b) shows carbon constituents of deconvoluted C1s core level peak vs. substrate bias voltage of 25 kHz frequency for 0.2 min process times corresponding to 1.8×10¹⁶ ions/cm² ion fluence for an FCVA process on a silicon substrate according to embodiments of the present disclosure.

FIG. 9(a) shows surface roughness vs. process time for 120 eV ion kinetic energy (e.g., −100 V bias voltage of 25 kHz frequency) for an FCVA process on a silicon substrate according to embodiments of the present disclosure. The zero-time data point in FIG. 9(a) corresponds to the roughness of the Ar⁺ sputter-cleaned Si(100) substrate surface. FIG. 9(b) shows surface roughness vs. substrate bias voltage of 25 kHz frequency for 0.4 min and 0.2 min process times corresponding to 3.6 and 1.8×10¹⁶ ions/cm² ion fluence for an FCVA process on a silicon substrate according to embodiments of the present disclosure.

FIG. 10(a) shows a graph of a nanoindentation curve and FIG. 10(b) shows maximum contact pressure vs. maximum displacement for a sample processed at 120 eV ion kinetic energy (e.g., −100 V bias voltage of 25 kHz frequency) and 3 min process time for an FCVA process on a silicon substrate according to embodiments of the present disclosure.

FIG. 11(a) shows effective hardness vs. process time for 120 eV ion kinetic energy (e.g., −100 V bias voltage of 25 kHz frequency), and FIG. 11(b) shows effective hardness vs. substrate bias voltage of 25 kHz frequency for 0.4 min and 0.2 min process times corresponding to 3.6 and 1.8×10¹⁶ ions/cm² ion fluence for an FCVA process on a silicon substrate according to embodiments of the present disclosure.

FIG. 12 shows T-DYN simulation of depth profiles for 20 eV and 120 eV ion kinetic energies, which correspond to 0 V and −100 V pulse bias, respectively for an FCVA process on a magnetic recording medium according to embodiments of the present disclosure.

FIG. 13 shows film thickness vs. deposition time for 0 V and −100 V pulse bias for an FCVA process on a magnetic recording medium according to embodiments of the present disclosure.

FIG. 14 shows an XPS spectrum of the C1s core level peak for an FCVA process on a magnetic recording medium according to embodiments of the present disclosure. Six Gaussian distributions were fitted to each XPS spectrum after performing Shirley background subtraction.

FIG. 15 shows a graph of carbon bonding vs. film thickness for an FCVA process on a magnetic recording medium according to embodiments of the present disclosure.

FIG. 16 shows AFM scans (1×μm²) showing surface morphology of FCVA carbon films on a magnetic recording medium according to embodiments of the present disclosure.

FIG. 17 shows a graph of film roughness vs. thickness in a graph of RMS roughness by AFM scans (1×μm²) for an FCVA-treated magnetic recording medium according to embodiments of the present disclosure.

FIG. 18 shows graphs of mechanical properties measured from nanoindentations for an FCVA-treated a magnetic recording medium according to embodiments of the present disclosure.

FIG. 19 shows a graph of a T-DYN simulation of etch thickness of graphitic carbon vs. incidence angle of an Ar⁺ ion beam for 500 eV ion energy and 1×10¹⁶ ions/cm² ion dose for a magnetic recording medium according to embodiments of the present disclosure.

FIG. 20(a) shows graphs of XPS spectrum of a hard-disk sample with a 4-nm-thick carbon overcoat obtained before sputter etching of the magnetic recording medium with an Ar⁺ ion beam according to embodiments of the present disclosure. FIG. 20(b) shows graphs of XPS spectrum of a hard-disk sample with a 4-nm-thick carbon overcoat obtained after 8 min of sputter etching of the magnetic recording medium with an Ar⁺ ion beam at an incidence angle of 60° according to embodiments of the present disclosure.

FIG. 21(a) shows graphs of carbon implantation profiles due to C⁺ ion impingement perpendicular to the surface of a cobalt substrate simulated with the T-DYN code for zero substrate bias and ion fluence in the range of (0.9-13.5)×10¹⁶ ions/cm² according to embodiments of the present disclosure. FIG. 21(b) shows graphs of carbon implantation profiles due to C⁺ ion impingement perpendicular to the surface of a semi-infinite medium composed of cobalt simulated with the T-DYN code for −100 V (25 kHz pulse frequency) substrate bias and ion fluence in the range of (0.9-13.5)×10¹⁶ ions/cm² according to embodiments of the present disclosure.

FIG. 22 shows a graph of surface elevation determined from surface profilometry measurements vs. treatment time for zero and −100 V (25 kHz pulse frequency) substrate bias and 1.5×10¹⁵ ions/cm²·s ion flux for an FCVA process on a magnetic recording medium according to embodiments of the present disclosure.

FIG. 23(a) shows graphs of Co 2p XPS spectra of magnetic medium obtained before FCVA treatment according to embodiments of the present disclosure. FIG. 23(b) shows graphs of Co 2p XPS spectra of magnetic medium obtained after FCVA treatment for zero substrate bias, 1.5×10¹⁵ ions/cm²·s ion flux, and 6 s treatment time according to embodiments of the present disclosure.

FIG. 24 shows graphs of C1s XPS spectrum of FCVA-treated magnetic medium for zero substrate bias, 1.5×10¹⁵ ions/cm²·s ion flux, and 12 s treatment time. After inelastic background subtraction, the spectrum was fitted with six Gaussian distributions at characteristic binding energies according to embodiments of the present disclosure.

FIG. 25(a) shows graphs of binding energies of sp¹, sp², and sp³ carbon hybridization vs. treatment time for zero substrate bias and 1.5×10¹⁵ ions/cm²·s ion flux for an FCVA process on a magnetic recording medium according to embodiments of the present disclosure. FIG. 25(b) shows graphs of binding energies of sp¹, sp², and sp³ carbon hybridization vs. treatment time for −100 V (25 kHz pulse frequency) substrate bias and 1.5×10¹⁵ ions/cm²·s ion flux for an FCVA process on a magnetic recording medium according to embodiments of the present disclosure.

FIG. 26(a) shows graphs of fractions of different carbon hybridizations vs. treatment time for zero substrate bias and 1.5×10¹⁵ ions/cm²·s ion flux for an FCVA process on a magnetic recording medium according to embodiments of the present disclosure. FIG. 26(b) shows graphs of fractions of different carbon hybridizations vs. treatment time for −100 V (25 kHz pulse frequency) substrate bias and 1.5×10¹⁵ ions/cm²·s ion flux for an FCVA process on a magnetic recording medium according to embodiments of the present disclosure.

FIG. 27 shows a graph of surface roughness (rms) vs. treatment time for zero and −100 V (25 kHz pulse frequency) substrate bias and 1.5×10¹⁵ ions/cm²·s ion flux for an FCVA process on a magnetic recording medium according to embodiments of the present disclosure.

FIG. 28(a) shows a graph of nanoindentation load vs. displacement response and FIG. 28(b) shows a graph of maximum (contact) pressure and reduced modulus vs. maximum displacement of FCVA-treated magnetic medium for zero substrate bias, 1.5×10¹⁵ ions/cm²·s ion flux, and 48 s treatment time according to embodiments of the present disclosure.

FIG. 29(a) shows a graph of effective hardness vs. treatment time of FCVA-treated magnetic medium for zero and −100 V (25 kHz pulse frequency) substrate bias and 1.5×10¹⁵ ions/cm²·s ion flux according to embodiments of the present disclosure. FIG. 29(b) shows a graph of reduced modulus vs. treatment time of FCVA-treated magnetic medium for zero and −100 V (25 kHz pulse frequency) substrate bias and 1.5×10¹⁵ ions/cm²·s ion flux according to embodiments of the present disclosure. FIG. 29(c) shows a graph of critical depth vs. treatment time of FCVA-treated magnetic medium for zero and −100 V (25 kHz pulse frequency) substrate bias and 1.5×10¹⁵ ions/cm²·s ion flux according to embodiments of the present disclosure. Both the effective hardness and the reduced modulus were calculated at the critical depth.

### DETAILED DESCRIPTION

Provided are filtered cathodic vacuum arc systems useful for modifying a surface of a substrate (e.g. depositing a thin film of a material onto a surface of a substrate and/or implanting a material into the near-surface region of a substrate). The systems are configured to stabilize a direct current (dc) arc discharge from an arc source. Also provided are methods for modifying a surface of a substrate, which in some cases includes depositing a material onto a surface of a substrate, in some cases includes implanting a material into the near-surface region of a substrate using the subject cathodic arc systems, and in some cases includes both depositing a material onto a surface of a substrate and implanting a material into the near-surface region of a substrate. In addition, magnetic recording media produced by the subject systems and methods are provided.

Before the present invention is described in greater detail, it is to be understood that this invention is not limited to particular embodiments described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, representative illustrative methods and materials are now described.

All publications and patents cited in this specification are herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present invention is not entitled to antedate such publication by virtue of prior invention. Further, the dates of publication provided may be different from the actual publication dates which may need to be independently confirmed.

It is noted that, as used herein and in the appended claims, the singular forms “a”, “an”, and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention. Any recited method can be carried out in the order of events recited or in any other order which is logically possible.

Below, the subject cathodic arc systems are described first in greater detail. In addition, methods of depositing and/or implanting a material onto a surface of a substrate are disclosed in which the subject systems may find use. Also disclosed are magnetic recording media produced by the subject systems and methods.

### Filtered Cathodic Vacuum Arc (FCVA)

Filtered cathodic vacuum arc (FCVA) is a type of cathodic arc process for modifying a surface of a substrate. Aspects of FCVA include plasma beam directionality, plasma energy adjustment via substrate biasing, macroparticle filtering, and independent substrate temperature control, each of which is discussed in more detail below. Cathodic arc systems may be configured in a direct current (dc) mode or a pulsed arc mode.

In certain embodiments, the cathodic arc system includes an arc source, a cathode magnetic field source, an upstream magnetic field source, a substrate holder, and a plasma conduit in communication with the arc source and the substrate holder. The system may be configured to stabilize a dc arc discharge plasma from the arc source. By “stabilize” is meant a reduction in fluctuations of the dc arc discharge plasma from the arc source and/or a reduction in the migration of arcing spots towards the edge of the surface of the arc source. By “reduction” is meant a decrease in the number or amount, frequency, duration, intensity, etc. of an event. For example, a reduction in fluctuations of the dc arc discharge plasma from the arc source may include a decrease in the number or amount, frequency, duration, intensity, etc. of fluctuations in the dc arc discharge plasma from the arc source as compared to a cathodic arc system that does not include the subject system. A reduction in the migration of arcing spots towards the edge of the surface of the arc source may include a decrease in the number or amount, frequency, duration, intensity, etc. of movement of arcing spots across the surface of the arc source as compared to a cathodic arc system that does not include the subject system.

In certain embodiments, a stabilization of the dc arc discharge plasma from the arc source facilitates maintaining the dc arc discharge current in a desired range for a desired period of time. Embodiments of the subject system may facilitate maintaining the dc arc discharge current within 30% or less of a desired dc arc discharge current, such as 25% or less, including 20% or less, or 15% or less, or 10% or less, or 5% or less, or 3% or less, or 1% or less of a desired dc arc discharge current. The dc arc discharge current may range from 10 A to 200 A, such as from 30 A to 150 A, including from 50 A to 100 A. In some cases, the dc arc discharge current is 70 A. Embodiments of the subject system may be configured to maintain a stable dc arc discharge plasma from the arc source for 0.1 sec or more, such as 0.2 sec or more, including 0.4 sec or more, or 0.7 sec or more, 1 sec or more, 5 sec or more, 10 sec or more, 20 sec or more, 30 sec or more, 40 sec or more, 50 sec or more, 60 sec or more, 70 sec or more 80 sec or more, 90 sec or more, 100 sec or more, for example, 2 min or more, such as 3 min or more, including 3 min or more, or 5 min or more, or 10 min or more, etc.

Systems of embodiments of the invention may be configured to provide the above described stabilization of the dc arc discharge plasma using any convenient configuration. In some cases, the cathode magnetic field and the upstream magnetic field sources are configured to produce opposite magnetic fields. As used herein, the term “upstream” refers to positions nearer to the arc source along the plasma conduit, and the term “downstream” refers to positions farther away from the arc source along the plasma conduit. In some cases, the plasma is generated by the arc source, travels through the plasma conduit, and contacts the surface of a substrate in the substrate holder.

In some instances, the cathode magnetic field and the upstream magnetic field sources are configured to produce a combined magnetic field. As indicated above, in certain embodiments, the magnetic field generated by the cathode magnetic field source is opposite to that produced by the upstream magnetic field source. The combined magnetic field may facilitate the stabilization of the dc arc discharge plasma by maintaining stable electron flow from the arc source (e.g., cathode) to the anode. In certain cases, the combined magnetic field has a magnetic field intensity ranging from 1 mT to 200 mT, such as 5 mT to 150 mT, including 10 mT to 100 mT, or 10 mT to 75 mT, such as 10 mT to 50 mT, and including 30 mT to 40 mT, at the surface of the arc source. For example, in some cases, the combined magnetic field has a magnetic field intensity of 34 mT at the surface of the arc source.

In certain embodiments, the cathode magnetic field source is a cathode magnetic coil. The cathode magnetic coil may have a current ranging from 5 A to 60 A, such as 15 A to 50 A, and including 20 A to 40 A, for example 25 A to 35 A. In some instances, the cathode magnetic coil has a current of 25.9 A. The cathode magnetic coil may be configured to produce a magnetic field intensity ranging from 10 mT to 200 mT, such as from 20 mT to 175 mT, including from 30 mT to 150 mT. In some instances, the cathode magnetic coil has a magnetic field intensity, normalized by the coil current, ranging from 0.5 mT/A to 5 mT/A, such as 1 mT/A to 3 mT/A, and including 1.5 mT/A to 2.5 mT/A. For example, the upstream magnetic field coil may have a magnetic field intensity, normalized by the coil current, of 2.2 mT/A.

In some cases, the upstream magnetic field source is an upstream magnetic coil. The upstream magnetic coil may have a current ranging from 5 A to 60 A, such as 15 A to 50 A, and including 20 A to 40 A, for example 25A to 35 A. In some cases, the upstream magnetic coil has a current of 30.5 A. The upstream magnetic coil may be configured to produce a magnetic field intensity ranging from 1 mT to 200 mT, such as from 5 mT to 150 mT, including from 10 mT to 100 mT. In some instances, the upstream magnetic coil has a magnetic field intensity, normalized by the coil current, ranging from 0.5 mT/A to 2 mT/A, such as 0.75 mT/A to 1.75 mT/A, and including 1 mT/A to 1.5 mT/A. For example, the upstream magnetic field coil may have a magnetic field intensity, normalized by the coil current, of 1.3 mT/A.

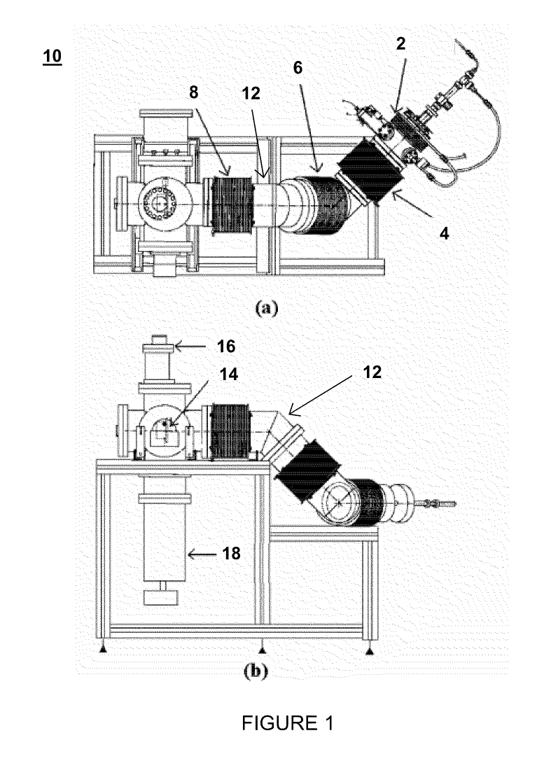

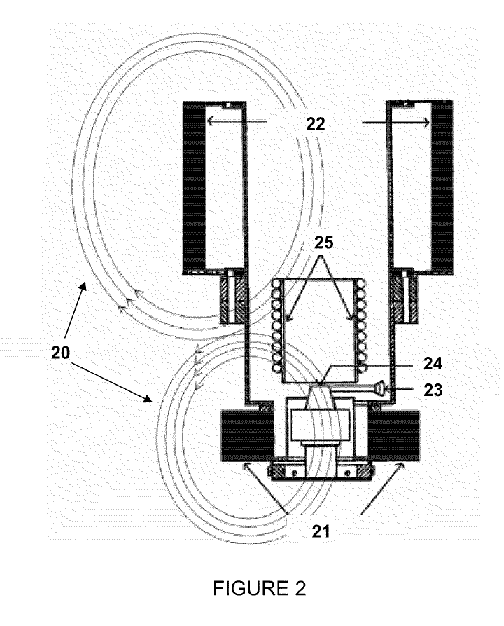

In certain embodiments, the arc source and the substrate holder are in a three-dimensional out-of-plane configuration. By “three-dimensional out-of-plane configuration” is meant that the arc source and the substrate holder are configured such that the arc source and the substrate holder do not lie in the same plane and the substrate holder is not aligned with the axis of emissions from the arc source. In some cases, the plasma conduit is also in a three-dimensional out-of-plane configuration. FIGS. 1 and 2 show schematics of cathodic arc deposition systems according to embodiments of the present disclosure.

In certain instances, the system further includes a downstream magnetic field source. In some cases, the system further includes an auxiliary magnetic field source.

The auxiliary magnetic field source may be positioned along the plasma conduit between the upstream magnetic field source and the downstream magnetic field source. In some cases, the system is configured to guide the plasma generated by arcing at the cathode through the plasma conduit to the substrate holder. The upstream, auxiliary, and downstream magnetic field sources may facilitate guiding the plasma toward the substrate holder. In certain embodiments, the magnetic fields of the upstream, auxiliary, and downstream magnetic field sources are of the same direction and are continuous within the plasma conduit.

In certain embodiments, the downstream magnetic field source is a downstream magnetic coil. The downstream magnetic coil may have a current ranging from 5 A to 60 A, such as 15 A to 50 A, and including 20 A to 40 A, for example 25A to 35 A. For example, the downstream magnetic coil may have a current of 29.6 A. The downstream magnetic coil may be configured to produce a magnetic field intensity ranging from 1 mT to 200 mT, such as from 5 mT to 150 mT, including from 10 mT to 100 mT. In certain embodiments, the downstream magnetic coil has a magnetic field intensity, normalized by the coil current, ranging from 0.5 mT/A to 2 mT/A, such as 0.75 mT/A to 1.75 mT/A, and including 1 mT/A to 1.5 mT/A. For example, the downstream magnetic field coil may have a magnetic field intensity, normalized by the coil current, of 1.2 mT/A.

In some cases, the auxiliary magnetic field source is an auxiliary magnetic coil. The auxiliary magnetic coil may have a current ranging from 5 A to 60 A, such as 15 A to 50 A, and including 20 A to 40 A, for example 25A to 35 A. For instance, the auxiliary magnetic coil may have a current of 30.9 A. The auxiliary magnetic coil may be configured to produce a magnetic field intensity ranging from 1 mT to 200 mT, such as from 5 mT to 150 mT, including from 10 mT to 100 mT. In certain embodiments, the auxiliary magnetic coil has a magnetic field intensity, normalized by the coil current, ranging from 0.5 mT/A to 2 mT/A, such as 0.75 mT/A to 1.75 mT/A, and including 1 mT/A to 1.5 mT/A. For example, the auxiliary magnetic field coil may have a magnetic field intensity, normalized by the coil current, of 1.2 mT/A.

In certain embodiments, the upstream, auxiliary, and downstream magnetic field sources facilitate filtering the plasma as the plasma travels through the plasma conduit. In some cases, the upstream, auxiliary, and downstream magnetic field sources are configured to guide the plasma through the three-dimensional out-of-plane configuration of the plasma conduit, while facilitating the filtering of the plasma. For example, the upstream, auxiliary, and downstream magnetic field sources may be configured to filter neutral macroparticles from the plasma.

In certain instances, system includes one or more raster magnetic field sources. The raster magnetic field sources may be positioned such that they facilitate positioning the plasma beam on the surface of the substrate. In certain instances, the one or more raster magnetic field sources are one or more raster magnetic coils. The raster magnetic field sources may be attached to the outside of the downstream magnetic field source. In some cases, the system includes 2, 4, 6, 8, 10, 12, or more raster magnetic coils.

In certain embodiments, the system includes an ion source, such as but not limited to an Ar⁺ ion source. In these cases, the ion source may be configured to clean the surface of the substrate prior to contacting the surface of the substrate with the plasma. For example, the surface of the substrate may be cleaned by Ar⁺ ion beam sputtering on the surface of the substrate. In certain embodiments, the incidence angle between the ion beam and the substrate surface ranges from 0° to 90°, such as from 30° to 90°, including from 60° to 90°. In some cases, the incidence angle between the ion beam and the substrate surface is 60°.

Aspects of the system may include a pulsed voltage source. The pulsed voltage source may be configured to apply a pulsed bias voltage to the substrate. In certain embodiments, the pulsed bias voltage ranges from 200 V to −500 V, such as from 100 V to −400 V, or from 50 V to −300 V, such as from 0 V to −300 V, including from 0 V to −200 V, such as from 0 V to −150 V, for example from 0 V to −100 V, and including from 0 V to −50 V. In some cases, the pulsed bias voltage has a pulse frequency ranging from 1 kHz to 200 kHz, such as from 1 kHz to 150 kHz, or from 1 kHz to 100 kHz, or from 5 kHz to 100 kHz, such as from 10 kHz to 75 kHz, and including from 10 kHz to 50 kHz. In certain cases, the pulsed bias voltage has a pulse frequency of 25 kHz.

In some instances, the system includes a vacuum source configured to create a vacuum within the cathodic arc deposition system. In some cases, the vacuum source is a vacuum pump, such as, but not limited to, a cryopump. The vacuum source may be configured to maintain a pressure within the cathodic arc deposition system of 1×10⁻⁵ Torr or less, such as 1×10⁻⁶ Torr or less, including 5×10⁻⁷ Torr or less, for example 1×10⁻⁷ Torr or less. In some cases, the vacuum source is configured to maintain a pressure within the cathodic arc deposition system of 3×10⁻⁷ Torr.

In certain embodiments, the system also includes a cooling system. The cooling system may be used to cool the cathode, the substrate, or both the cathode and the substrate. In some cases, the cooling system uses a coolant, such as but not limited to water, where the water may be cold water, such as water having a temperature below room temperature.

In some instances, the system includes an arc source, where the arc source comprises a metal, a ceramic, or a composite material, such as, but not limited to TiN, TiAlN, Al₂O₃, Cr₂O₃, CrN, ZrN, TiAlSiN, and the like. In some cases, the arc source includes a carbon cathode, such as but not limited to a graphite cathode. In these cases, the cathodic arc deposition system may be configured to deposit carbon on the surface of the substrate. The carbon deposited on the surface of the substrate can be amorphous carbon, such as but not limited to tetrahedral amorphous carbon (e.g., diamond-like carbon).

FIG. 1(a) shows a schematic of a top view of a cathodic arc system 10 according to embodiments of the present disclosure. The cathode magnetic coil 2 and the upstream magnetic coil 4 may be configured to stabilize a dc arc discharge from the arc source. The auxiliary magnetic coil 6 and the downstream magnetic coil 8 may be configured to guide the plasma generated at the arc source through the plasma conduit 12 to the substrate holder 14. FIG. 1(b) shows a schematic of a side view of a cathodic arc system 10 according to embodiments of the present disclosure. As described above, the plasma conduit 12 may have a three-dimensional out-of-plane configuration. Ion source 16 may be configured to clean the surface of the substrate by Ar⁺ ion beam sputtering on the surface of the substrate. Cryopump 18 may be configured to create a vacuum within the cathodic arc system 10.

FIG. 2 shows a schematic of a cross section of the plasma-stabilizing mechanism during dc arc discharge according to embodiments of the present disclosure. The magnetic field lines 20 produced by the cathode coil 21 and the upstream coil 22 are shown only at the left side of the coil cross section for clarity. A mechanical trigger 23 may be configured to contact the cathode 24 to initiate the dc arc discharge from the cathode 24 to the anode 25.

The substrate may be any substrate for which it is desired to deposit a material onto its surface or implant a material into the near-surface region of the substrate by using the subject cathodic arc systems. For example, the substrate may include silicon, such as but not limited to a silicon wafer. In some embodiments, the substrate comprises a magnetic recording medium, such as but not limited to a magnetic hard disk. Additionally, the substrate may be a magnetic recording head, such as but not limited to, a magnetic recording head, a ceramic magnetic recording head, and the like. In certain embodiments, the substrate is configured to be removeably attached to the substrate holder. The substrate may be rotated to facilitate uniform modification of the surface of the substrate. For example, the substrate holder may be configured to rotate about an axis substantially perpendicular to the surface of the substrate, such that the surface of the substrate in the substrate holder is uniformly modified.

### Substrates

Aspects of the present disclosure also include a substrate produced by the subject systems and methods. In certain cases, the substrate includes a cathode material deposited onto a surface of the substrate. The cathode material may be deposited as a thin film layer on the surface of the substrate. In some cases, the substrate includes a thin near-surface region that has been compositionally modified to include a cathode material using the subject cathodic arc systems and methods. In these cases, the cathode material is implanted into the near-surface region of the substrate. Embodiments of the substrate include a substrate layer that includes a substrate material and a thin near-surface layer that includes the substrate material and the cathode material. In some cases, the near-surface layer includes the substrate material intermixed with the cathode material.

In certain embodiments, the thin near-surface layer has a thickness of 10 nm or less, such as 5 nm or less, including 2 nm or less, for example 1 nm or less. As used herein, the terms “near-surface layer” and “near-surface region” refer to the layer or region of a substrate at the surface of the substrate that is modified by the subject systems and methods. In some cases, the thin near-surface layer has a thickness ranging from 0.1 nm to 10 nm, such as from 0.1 nm to 5 nm, including from 0.1 nm to 2 nm, for example from 0.1 nm to 1 nm.

In certain embodiments, the thin near-surface layer has an effective hardness ranging from 1 GPa to 100 GPa, such as from 1 GPa to 80 GPa, and including from 1 GPa to 60 GPa. In some instances, the thin near-surface layer has an average surface roughness ranging from 0.01 nm to 1 nm, such as from 0.03 nm to 0.5 nm, and including from 0.05 nm to 0.2 nm. The thin near-surface layer may include amorphous carbon, such as but not limited to tetrahedral amorphous carbon (e.g., diamond-like carbon). In these cases, the thin near-surface layer has a percent fraction of sp³-hybridized carbon ranging from 10% to 100%, such as from 10% to 99%, or from 10% to 95%, or from 10% to 90%, such as from 15% to 75%, and including from 20% to 60%. For example, the thin near-surface layer may have a percent fraction of sp³-hybridized carbon of 20% or greater, or 30% or greater, or 40% or greater, or 50% or greater, such as 60% or greater, including 70% or greater, or 80% or greater, or 90% or greater, or 95% or greater, or 99% or greater.

### Magnetic Recording Media

As described above, in certain embodiments, the substrate includes a magnetic recording medium. The terms “magnetic recording medium” and “magnetic storage medium” refer to a form of non-volatile memory that is configured to store data on a magnetizable substrate. “Non-volatile memory” refers to memory that can retain stored information even when not powered. Examples of magnetic recording media include, but are not limited to, hard disks, floppy disks, magnetic recording tapes, magnetic stripes on credit cards, and the like.

In certain embodiments, the magnetic recording medium includes a hard disk. By “hard disk” is meant a non-volatile memory that stores digitally encoded data on a magnetic substrate. The hard disk may be included in a hard disk drive. The hard disk drive may include a drive mechanism configured to rotate the hard disk and a magnetic recording head configured to read and write data to the hard disk. One or more hard disks may be included in the hard disk drive, such as 2 or more, 3 or more, 4 or more, 5 or more, 10 or more, or 15 or more hard disks, etc. In some cases, the drive mechanism is configured to rotate the hard disk at a frequency of 5,400 rpm or greater, such as 7,200 rpm or greater, including 15,000 rpm or greater.

The hard disk can include several layers disposed over each other. In some cases, the hard disk includes a magnetic storage layer, a thin carbon film disposed over the magnetic layer, and a lubricant layer disposed over the thin carbon film. The thin carbon film may be configured to minimize corrosion and mechanical wear of the underlying magnetic storage layer. The lubricant layer may be configured to provide an additional barrier against corrosion and also minimize friction whenever intermittent asperity contact occurs between the magnetic recording head and the hard disk. The term “asperity” refers to the summits (e.g., peaks) of a surface of a substrate due to, e.g., surface projections, and the like.

The magnetic recording density of the hard disk may depend on various factors, such as the distance between the magnetic storage layer of the hard disk and the magnetic recording head. By “magnetic recording density” is meant the amount of data per unit area that can be stored on a magnetic recording medium. In certain embodiments, the distance between the hard disk and the magnetic recording head is 10 nm or less, such as 5 nm or less, including 3 nm or less, or 2 nm or less, or 1 nm or less, or 0.5 nm or less. For example, the magnetic recording density may increase as the distance between the magnetic storage layer of the hard disk and the read/write transducer at the trailing edge of the magnetic recording head decreases. A minimization of the distance between the magnetic storage layer of the hard disk and the read/write transducer of the magnetic recording head may facilitate a maximization in the magnetic recording density of the hard disk. For instance, a minimization in the thickness or elimination of one or more layers disposed over the magnetic storage layer may facilitate a maximization in the magnetic recording density.

In certain embodiments, the magnetic recording medium includes a substrate layer and a magnetic storage layer disposed over the substrate layer, where the magnetic storage layer includes a magnetic storage material. A cathode material may be deposited onto a surface of the magnetic recording medium. For example, the cathode material may be disposed over the magnetic storage layer. In some cases, the cathode material is deposited as a thin film layer on the surface of the magnetic storage layer. In certain instances, the magnetic recording medium includes a thin near-surface region near the surface of the magnetic recording medium, such as near the surface of the magnetic storage layer. The thin near-surface region may be compositionally modified to include a cathode material. In some cases, the cathode material is implanted into the thin near-surface region of the magnetic storage layer, such that the thin near-surface region of the magnetic storage layer includes the magnetic storage material and the cathode material. In some cases, the cathode material is both deposited as a thin film on the surface of the magnetic storage layer and implanted into the near-surface region of the magnetic storage layer.

In certain embodiments, the cathode material deposited onto the surface of the magnetic recording medium and/or implanted into the near-surface region of the magnetic recording medium (or both deposited and implanted) is configured to minimize corrosion and mechanical wear of the underlying magnetic storage layer. In some instances, the magnetic recording medium does not have a lubricant layer disposed on the surface of the magnetic recording medium. A magnetic recording medium that does not have a lubricant layer may facilitate a minimization of the distance between the magnetic storage layer and the magnetic recording head. For example, the distance between the magnetic storage layer and the magnetic recording head may be 10 nm or less, such as 5 nm or less, including 3 nm or less, or 2 nm or less, or 1 nm or less, or 0.5 nm or less. A minimization of the distance between the magnetic storage layer and the magnetic recording head may facilitate a maximization in the magnetic recording density of the magnetic recording medium. In certain embodiments, the magnetic recording medium has a magnetic recording density of 5 Tbit/in² or greater, such as 10 Tbit/in² or greater, including 20 Tbit/in² or greater, or 50 Tbit/in² or greater, or 100 Tbit/in² or greater.

### Methods

Embodiments of the present disclosure include a method of modifying a surface of a substrate with a cathode material, the method including the steps of: producing a plasma from an arc source; generating a combined magnetic field from a cathode magnetic field source and an upstream magnetic field source to obtain at least one of a stabilized plasma and a filtered plasma; and contacting the plasma with a surface of a substrate to modify the surface of the substrate with the material. The cathode magnetic field and upstream magnetic field sources may have opposite magnetic fields. In certain embodiments, the contacting includes depositing the cathode material onto the surface of the substrate. In some embodiments, the contacting includes implanting the cathode material into the surface of the substrate. The contacting may also include both depositing the cathode material onto the surface of the substrate and implanting the cathode material into the surface of the substrate.

In some instances, the method includes directing the plasma through a plasma conduit, where the plasma conduit is configured in a three-dimensional out-of-plane configuration, as described in detail above. The directing may include adjusting the current in one or more of the upstream, auxiliary, and downstream magnetic field sources to facilitate guiding the plasma through the plasma conduit toward the surface of the substrate. In some embodiments, the directing also facilitates filtering macroparticles (e.g., atom clusters) out of the plasma before contacting the surface of the substrate.

In some cases, the method includes cleaning the surface of the substrate before contacting the plasma with the surface of the substrate. The cleaning can include contacting the substrate surface with ions produced from an ion source, such as but not limited to an Ar⁺ ion source. The substrate surface may be cleaned prior to contacting the surface of the substrate with the plasma. For example, the cleaning may include Ar⁺ ion beam sputtering on the surface of the substrate.

Further embodiments of the subject methods include the step of cooling the substrate. The cooling may include contacting the substrate with a coolant, such that heat exchange occurs between the substrate and the coolant. In some instances, the coolant includes water, where the water may be cold water, such as water having a temperature below room temperature. The method may include monitoring the temperature of the substrate. In some cases, the method includes adjusting the flow of the coolant contacting the substrate such that the temperature of the substrate does not exceed a threshold temperature or such that the temperature of the substrate is maintained within a desired range.

In certain embodiments, the method includes applying a pulsed bias voltage to the substrate. As described above, in some cases, the pulsed bias voltage ranges from 200 V to −500 V, such as from 100 V to −400 V, or from 50 V to −300 V, such as from 0 V to −300 V, including from 0 V to −200 V, such as from 0 V to −150 V, for example from 0 V to −100 V, and including from 0 V to −50 V. In certain embodiments, the method includes adjusting the duty cycle (e.g., the on/off time ratio, or the fraction of time that a system is in an “on” state) of the pulsed bias voltage applied to the substrate. Adjusting the duty cycle of the pulsed bias voltage facilitates controlling the amount of cathode material deposited onto the surface of the substrate compared to the amount of cathode material implanted into the near-surface region of the substrate. For example, increasing the substrate biasing may facilitate a decrease in the amount of cathode material deposited onto the surface of the substrate. Increasing the substrate biasing may also facilitate an increase in the amount of cathode material implanted into the near-surface region of the substrate. In some cases, the pulsed bias voltage has a pulse frequency ranging from 1 kHz to 200 kHz, such as from 1 kHz to 150 kHz, or from 1 kHz to 100 kHz, or from 5 kHz to 100 kHz, such as from 10 kHz to 75 kHz, and including from 10 kHz to 50 kHz. In certain cases, the pulsed bias voltage has a pulse frequency of 25 kHz.

As discussed above, embodiments of the subject method include depositing a cathode material onto a surface of a substrate, implanting the cathode material into the near-surface region of the substrate, or both depositing the cathode material onto the surface of a substrate and implanting the cathode material into the near-surface region of the substrate. Applying a pulsed bias voltage to the substrate may facilitate implantation of the cathode material into the near-surface region of the substrate. Implantation of the cathode material into the near-surface region of the substrate may occur by conventional implantation and/or recoil implantation. By “conventional implantation” is meant a process that uses accelerated ions to penetrate the surface of a substrate, thus implanting the ions into the substrate. By “recoil implantation” is meant a process that uses accelerated ions to drive material from a film disposed on a surface of a substrate into the substrate as a result of collisions between the film and the incident ions.

### Utility

The subject cathodic arc systems and methods find use in a variety of different applications where it is desirable to deposit thin films of a material onto the surface of a substrate or modify the chemical composition of the near-surface region of a substrate. The subject systems and methods find use in many applications, such as but not limited to the deposition of thin films onto the surface of a substrate, or the modification of the chemical composition of the near-surface region of a substrate. The subject systems and methods find use in the deposition of thin films onto surfaces or the modification of the chemical composition of the near-surface region of a variety of substrates, such as, but not limited to, the surfaces of magnetic recording heads, silicon wafers, cutting tools, pipelines, and the like. In some cases, the substrate may be a magnetic recording medium.

In certain embodiments, the subject cathodic arc systems can be used to deposit a thin diamond-like carbon film onto a substrate surface. In some cases, the subject cathodic arc systems can be used to produce a chemically modified near-surface region that includes the substrate material and a cathode material by implanting the cathode material into the surface of the substrate. The cathode material may include carbon (such as graphite) and the implanted material may include amorphous carbon. In some cases, the implanted amorphous carbon has a percent fraction of sp³-hybridized carbon ranging from 10% to 90%, such as from 15% to 75%, and including from 20% to 60%.

The subject cathodic arc systems and methods can be used to protect the magnetic layer of a magnetic recording medium against mechanical wear and corrosion. The subject systems and methods find use in providing desired tribological properties to a substrate, such as anti-wear, anti-friction, and corrosion resistance to the substrate. By “tribology” or “tribological” is meant to refer to the interaction between surfaces in relative motion, and can include interactions such as, but not limited to, friction, lubrication, wear, and the like. In addition, the thin films and modified near-surface region compositions produced by the subject systems and methods provide for effective bonding of a lubricant monolayer to the surface of the substrate, which may facilitate a reduction in friction.

In addition, the subject systems and methods can be used to deposit very thin films (e.g., thin films with a thickness of 10 nm or less, such as 5 nm or less, including 2 nm or less, or 1 nm or less) onto the surface of the magnetic layer of a magnetic recording medium. The subject systems and methods also find use in modifying the chemical composition of the near-surface region of the magnetic recording medium. In some cases, the near-surface region of the magnetic recording medium is modified to a depth of 10 nm or less, such as 5 nm or less, including 2 nm or less, for example 1 nm or less. In certain embodiments, modification of the surface of the magnetic recording medium allows for magnetic recording densities of 5 Tbit/in² or greater, such as 10 Tbit/in² or greater, including 20 Tbit/in² or greater, or 50 Tbit/in² or greater, or 100 Tbit/in² or greater.

As can be appreciated from the disclosure provided above, the present disclosure has a wide variety of applications. Accordingly, the following examples are offered for illustration purposes and are not intended to be construed as a limitation on the invention in any way. Those of skill in the art will readily recognize a variety of noncritical parameters that could be changed or modified to yield essentially similar results. Thus, the following examples are put forth so as to provide those of ordinary skill in the art with a complete disclosure and description of how to make and use the present invention, and are not intended to limit the scope of what the inventors regard as their invention nor are they intended to represent that the experiments below are all or the only experiments performed. Efforts have been made to ensure accuracy with respect to numbers used (e.g. amounts, temperature, etc.) but some experimental errors and deviations should be accounted for. Unless indicated otherwise, parts are parts by weight, molecular weight is weight average molecular weight, temperature is in degrees Celsius, and pressure is at or near atmospheric.

### EXAMPLES

### Example 1

### FCVA on Silicon Substrates

### I. Introduction

Filtered cathodic vacuum arc (FCVA) deposition and the properties of thin films synthesized by FCVA were studied. FCVA was studied by holding the process time, which is linearly related to the ion fluence, constant and adjusting the substrate bias. X-ray photoelectron spectroscopy (XPS) was used to examine carbon bonding changes in terms of implanting ion fluence and substrate bias. Film thickness and composition depth profiles were determined from T-DYN simulations and X-ray reflectivity (XRR) measurements. The film roughness, measured with an atomic force microscope (AFM), was analyzed in terms of atomic carbon bonding and carbon atom diffusion at the film surface. The nanomechanical properties of the films were detected with a surface force microscope (SFM).

### II. Experimental Procedures

A. Synthesis of carbon films by FCVA

Synthesis of carbon films on Si(100) substrates was performed with a direct current (dc) FCVA system by applying constant potential and current between the anode and cathode of 24 V and 70 A, respectively. The cathode and the anode were configured to generate a magnetic field that facilitates the stabilization of the dc arc discharge. Carbon ions arrived at the substrate surface at a flux rate of 1.48×10¹⁵ ions/cm²·s. The system was configured to filter macroparticles with a three-dimensional out-of-plane S-configuration magnetic filter. The substrate was pulsed biased at a frequency of 25 kHz with a voltage of average value varying from 0 V to −300 V. The FCVA experiments were performed on 4-inch-diameter Si(100) wafers which were first sputter-cleaned for 3 min with a 500 eV, 16 mA Ar⁺ ion beam at 60° incidence angle. During sputter cleaning and FCVA processing, the substrate holder was rotated at 60 rpm to obtain an etched layer and a carbon film of uniform thickness. A cryogenic pump was used to maintain a base pressure of less than 3×10⁻⁷ Torr in the FCVA system.

B. Thickness and Compositional Profiles

Binary atom collisions during the FCVA process were simulated by classical trajectory method using T-DYN software (version 4.0) to give composition profiles. The ion energy and ion fluence, measured experimentally, were the input parameters in the T-DYN simulations. T-DYN simulations were performed to a substrate depth of 20 nm from the top surface layer in 100 evenly split channels. The binding energy for Si and C were set to the standard values for solid-state silicon and graphite of 2.32 eV and 2.27 eV, respectively, and the corresponding surface binding energies to 4.7 eV and 7.41 eV, respectively. The impinging ion energy was set equal to the summation of the initial carbon ion energy of 20 eV (statistically, the most likely value) and the energy due to the substrate biasing (ranging from 0-300 eV). All ions were assumed to impinge the substrate surface in the normal direction.

Film thickness measurements were obtained by XRR (X′Pert PRO MRD, PANalytical, The Netherlands) with an X-ray wavelength of 0.154052 nm produced by a Cu—Kα X-ray tube. The generator current and voltage were set at 40 mA and 45 kV, respectively, and the step size at 0.005°, and the step time at 0.5 s.

C. Microstructure Analysis

The synthesized carbon films were characterized by an XPS system (PHI 5400, Physical Electronics; Chanhassen, Minn.) equipped with a monochromatic X-ray source of Al—Kα (1486.6 eV). XPS provided quantitative information about the bonding energy and bonding percentage of linear (sp¹), trigonal (sp²), and tetrahedral (sp³) carbon hybridizations, and high energy contamination bondings. In addition, XPS has a detection depth of about 10 nm and detected the overall bonding state of films with thickness 10 nm or less. Survey scans were acquired in 1 eV energy steps with pass energy of 178.95 eV. Each XPS survey spectrum was obtained as an average of four survey scans. For high-resolution scanning, the spectrometer was operated at pass energy of 35.75 eV and the energy step was set to 0.05 eV applied in 50 ms increments. Each high-resolution XPS window spectrum was obtained as an average of 20 scans. The area resolution of the XPS analyzer was 1 mm². The pressure in the XPS analyzing vacuum chamber was maintained at 2×10⁻⁸ Torr or less. The samples were not sputter cleaned before the XPS analysis.

A mechanical stylus profilometer (Dektak 3030 Surface Profiler, Veeco Instruments, Plainview, N.Y.) with a height resolution of 0.1 nm was used to measure the height difference between treated and untreated (covered during treatment) surface regions of each sample. The root-mean-square (rms) surface roughness of the carbon films was measured with an AFM (Dimension 3100, Veeco Instruments; Plainview, N.Y.) using 1×1 μm² scan areas. The AFM was operated in tapping mode, using a drive frequency of 259.332 kHz and scan rate of 2 Hz.

D. Nanomechanical Testing

The surface nanomechanical properties of the carbon films were analyzed with a SFM that included an AFM (Nanoscope II, Veeco Instruments; Plainview, N.Y.) retrofitted with a capacitive force transducer (Triboscope, Hysitron, Minneapolis, Minn.) having either a sharp diamond tip of radius 67 nm or a pyramidal diamond tip of nominal radius 75 nm. The tip area function versus indentation depth was obtained from a calibration with a fused quartz standard with in-plane modulus equal to 69.6 GPa. The triangular loading function with both loading and unloading times equal to 2 s was used in all nanoindentations. The hardness was measured as the ratio of the maximum load to the projected contact area of the diamond tip at the corresponding indentation depth. The in-plane elastic modulus (hereafter referred to as the reduced modulus) was calculated from the stiffness obtained as the slope of the unloading curve at the point of maximum tip displacement.

### III. Results And Discussion

A. Film Thickness and Composition Profiles

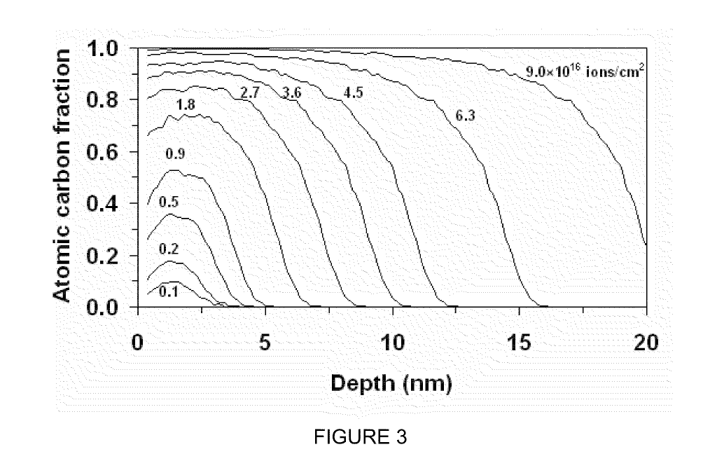

T-DYN simulations were first performed for carbon ion energy of 120 eV. FIG. 3 shows graphs of carbon depth profiles in silicon for carbon ion fluence in the range of 0.1−9.0×10¹⁶ ions/cm². An increase in the ion fluence increased the amount of carbon (e.g., cathode material) implanted into the near-surface region of the substrate. An increase in the ion fluence also increased the depth of penetration the carbon had into the silicon substrate (e.g., greater than 20 nm depth). For low ion fluence (e.g. less than 1.0×10¹⁶ ions/cm²), the maximum amount of carbon implanted into the near-surface region of the substrate occurred at a distance of about 1.5 nm below the surface (e.g., the average stopping range of 120 eV carbon ions in silicon). An atomic fraction of carbon of about 80 atomic % was reached at the surface for an ion fluence of 1.8×10¹⁶ ions/cm², which caused the carbon to penetrate to a depth of about 6 nm. An atomic fraction of carbon of 90 atomic % or greater was reached in the near-surface region for an ion fluence of 6.3×10¹⁶ ions/cm² or greater, which caused the carbon to penetrate to a depth of about 10 nm or greater.

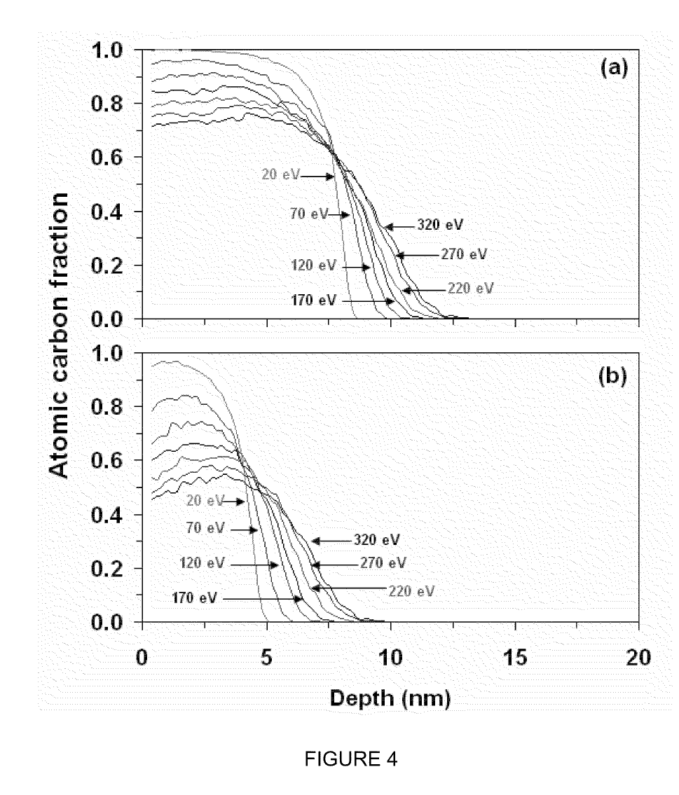

FIG. 4 shows graphs of T-DYN simulation results showing the effect of carbon ion energy (or substrate bias) under fixed ion fluences on the carbon depth profile for a silicon substrate. The ion fluences of 3.6×10¹⁶ ions/cm² (FIGS. 4(a)) and 1.8×10¹⁶ ions/cm² (FIG. 4(b)) correspond to process times of 0.4 min and 0.2 min, respectively. A comparison of FIGS. 4(a) and 4(b) indicated that the amount of carbon deposited on the silicon surface increased with ion fluence and decreased with an increase in ion kinetic energy. The thickness of the carbon-modified near-surface region increased with the ion kinetic energy and ion fluence. The shallowest carbon profile (e.g., 5 nm) of high surface carbon content (e.g., 95 atomic %) resulted from 20 eV ion kinetic energy and 1.8×10¹⁶ ions/cm² ion flux, e.g., 0.2 min process time without substrate bias (see FIG. 4(b)). High ion energy increased the depth of implantation of carbon ions into the near-surface region of the substrate, resulting in a broadening of the carbon depth profile. Low ion kinetic energy resulted in a carbon (e.g., 95 atomic % C) film of thickness 2 nm (see FIG. 4(b)).

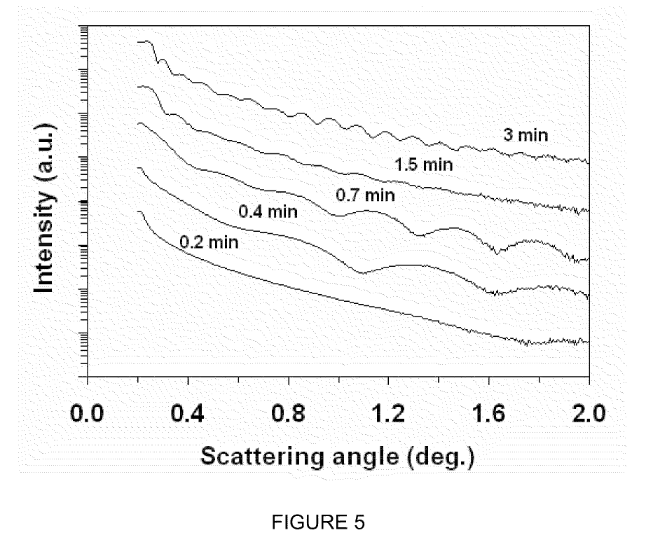

In the T-DYN simulations a uniform ion impinging energy was assumed and chemical reactions, diffusion, and atomic bond formation were neglected because they produce insignificant localized effects on the composition. XRR measurements were used to validate the T-DYN results. The intensity of the reflected X-ray depends on the surface and near-surface electron density. For example, intensity of the reflected X-ray depends on the depth where the carbon fraction decreases sharply. FIG. 5 shows XRR curves for 120 eV ion kinetic energy, e.g., −100 V, pulsed substrate bias for an FCVA process on a silicon substrate. The periodic fringe patterns are related to the X-ray travel length through the sample surface. The calculated depth of the X-ray reflection was determined by performing a fast Fourier transform of the periodic curves and was found to be 40.2 nm, 27.1 nm, 12.5 nm, 6.7 nm, and 2.3 nm for process times of 3.0 min, 1.5 min, 0.7 min, 0.4 min, and 0.2 min, respectively. The 2.3 nm, 6.7 nm, and 12.5 nm depths were close to the shoulder edge of the T-DYN simulation profiles for ion fluence equal to 1.8, 3.6, and 6.3×10¹⁶ ions/cm², respectively (see FIG. 3). The critical angle in the XRR curves may depend on the ion fluence and the density of the surface layer. For example, a decrease in the density of the surface layer may result in a decrease in the critical angle in the XRR curves as the ion fluence decreases.

B. Microstructure and Associated Mechanisms

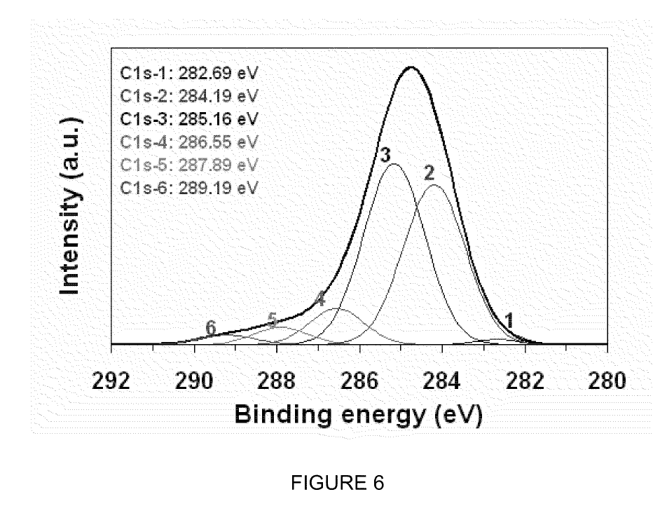

FIG. 6 shows a deconvoluted XPS C1s peak corresponding to 170 eV ion kinetic energy (e.g., −150 V pulsed substrate bias voltage of 25 kHz frequency) and 0.4 min process time for an FCVA process on a silicon substrate. Six Gaussian profiles with characteristic binding energies were fitted to the C1s peak after performing a Shirley inelastic background subtraction, and each profile was associated with a carbon constituent of a certain chemical state. Peaks C1s-1, C1s-2, and C1s-3 correspond to sp¹-, sp²- and sp³-coordinated carbon hybridizations, respectively, while peaks C1s-4, C1s-5, and C1s-6 correspond to carbon bonding to surface adsorbants and, hereafter, will be referred to as satellite peaks. The sum of the satellite peak areas indicated the percentage of surface-adsorbent related carbon bonding. The respective fraction of each bonding can be estimated by calculating the area of the corresponding peak.

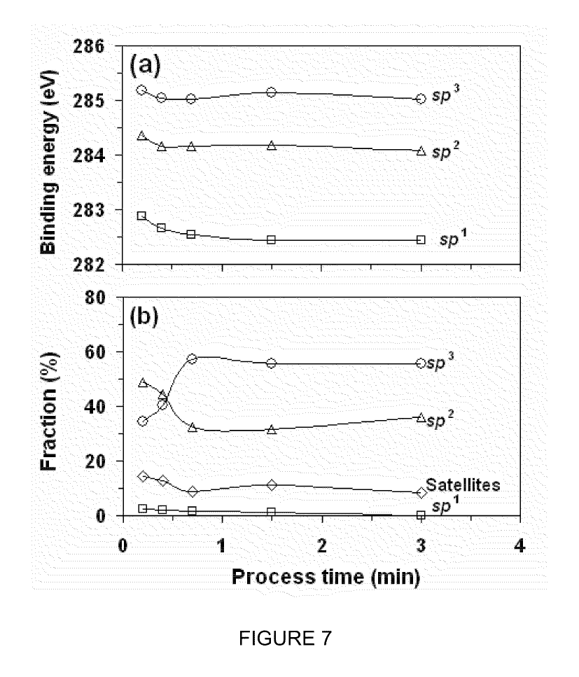

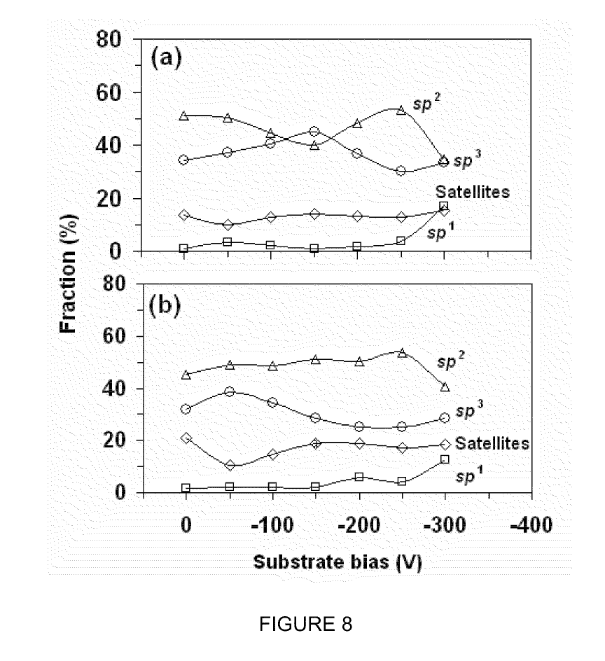

A change in carbon hybridization was observed with a decrease of the ion fluence. For an ion kinetic energy of 120 eV, the binding energies corresponding to sp¹, sp², and sp³ hybridizations did not significantly change as the process time increased, except for very short process times, e.g., very shallow depth profiles (see FIG. 7(a)). The higher binding energies obtained for relatively short process times (e.g., less than 0.5 min) correlated with a significant decrease in sp² hybridization and a significant increase in sp³ hybridization (see FIG. 7(b)). Low-ion-fluence FCVA was further studied with XPS by varying the substrate bias. FIG. 8 shows the variation of different carbon bonding with the substrate bias for short process times for an FCVA process on a silicon substrate. The satellite fractions are related to physical adsorption of airborne contaminants, depending on the film microstructure and surface carbon bonding, e.g., unstable carbon at the surface may easily react with ambient contaminants. These reactions can cause a decrease in the sp³ content. The highest sp³ content (e.g. 45%) was obtained with −150 V substrate bias voltage for process time of 0.4 min (see FIG. 8(a)). Decreasing the process time to 0.2 min and changing the bias voltage to −50 V resulted in a shallower carbon profile with a maximum sp³ content of 40% (see FIG. 8(b)). The high sp¹ and low sp² contents obtained under a substrate bias voltage of −300 V may be attributed to chemical reaction of C with Si. X-ray diffraction showed the formation of nanocrystalline SiC at the carbon-silicon interface. When carbon was bonded with silicon, a significant sp¹ peak (C1s-1 position) was observed in the deconvoluted XPS C1s peak. For an average ion kinetic energy of 320 eV, a significant portion of the ion energy distribution may be above the activation energy of SiC and, therefore, the sp¹ hybridization may be related to both carbon-carbon and carbon-silicon linear bonding.

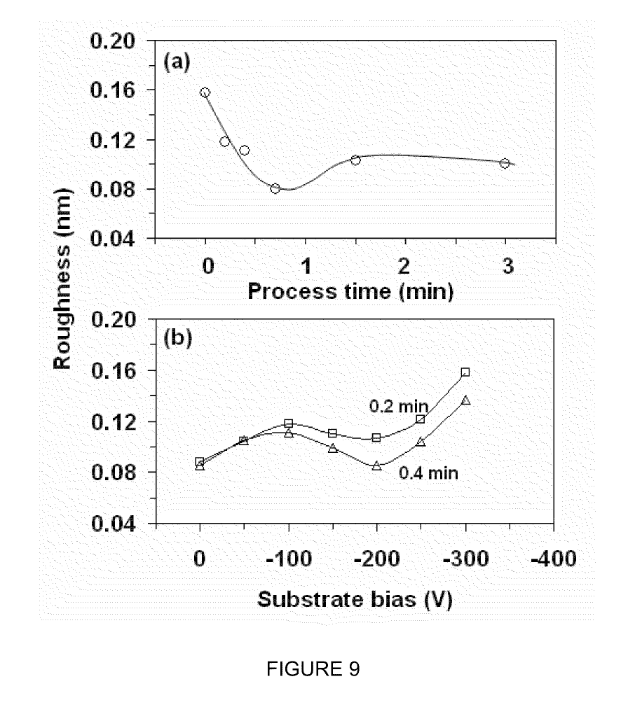

FIG. 9 shows graphs of surface roughness at the initial stage of surface modification and additional information regarding sp³ formation for an FCVA process on a silicon substrate. Lower sp³ content results in higher surface roughness, and higher sp³ content results in lower surface roughness. In some cases, the surface roughness for ultrathin films may be due in, part to the roughness of the underlying silicon substrate. In FIG. 9(a), the data point at zero process time corresponds to the Ar⁺ sputter-cleaned silicon substrate. As process time increased, the surface roughness decreased from the initial roughness. A minimum in roughness was observed at a process time of 0.7 min. Roughness increased slightly with process times between 07 min and 1.5 min and then the roughness gradually decreased for process times greater than 1.5 min. The process time of 0.7 min may correspond to the transition from relatively low to high carbon concentration profile and the greatest effect of surface smoothening by carbon atom adsorption. The roughness values for longer process times correspond to carbon profiles with increased sp³ contents. The decrease of the surface roughness process times greater than 1.5 min may be related to the increase of the ion fluence, which promoted surface smoothening through the increase of the amount of carbon delivered to the surface. The low surface roughness for 0 and −50 V bias voltage shown in FIG. 9(b) for fixed ion fluence may be attributed to a greater affinity of carbon atoms to adsorb and diffuse at the substrate surface, resulting in a smoothening effect. A local roughness peak was reached at a −100 V bias voltage due to deeper ion penetration and less carbon species at the surface resulting from the higher ion energy. The decrease in surface roughness for bias voltage between −100 and −200 V can be associated with the lower sp³ content of the film profiles causing a slight increase in resputtering and surface smoothening by low-degree surface diffusion. The significant roughening caused for bias voltage above −200 V was due to the intense bombardment of carbon ions that caused excessive atomic diffusion and surface damage.

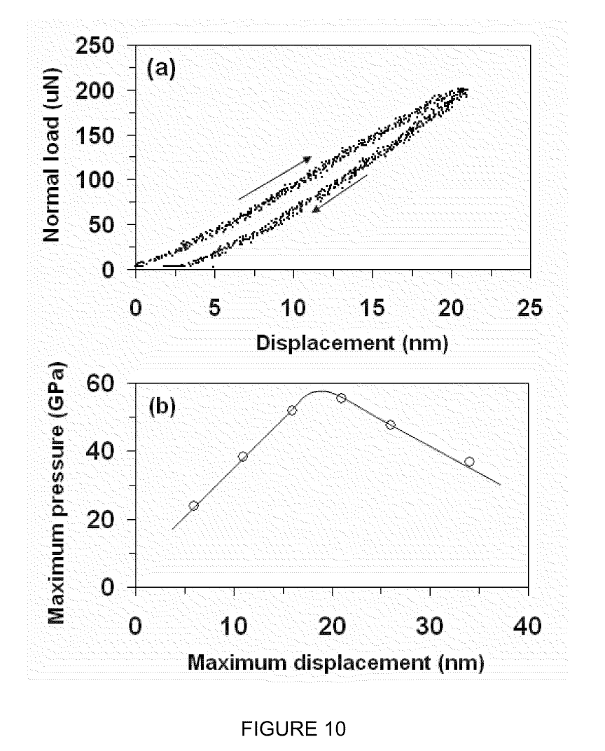

C. Nanomechanical Behavior FIG. 10(a) shows a graph of nanoindentation experiments for a sample processed at 120 eV ion kinetic energy and 3 min process time for an FCVA process on a silicon substrate. The surface resisted plastic deformation as can be seen in the small residual displacement after unloading and force hysteresis defined by the loading and unloading paths of the nanoindentation curve. The formation of the carbon film by FCVA increased the surface resistance to plastic deformation and decreased the force hysteresis as compared to the silicon control substrate. Using such force versus displacement curves, the maximum contact pressure was calculated by dividing the maximum indentation load by the projected area, determined from the tip shape function at the maximum displacement. FIG. 10(b) shows that the variation of the maximum pressure with the maximum displacement included two regions, a first region at lower maximum displacement and a second region at higher maximum displacement. In the first region, the contact pressure increased as plastic deformation accumulated below the tip, reaching a maximum pressure of 58 GPa at a maximum displacement of 20 nm. In the second region, the maximum pressure decreased as the maximum displacement increased above 20 nm. The decrease of the contact pressure in the second region was due to the more pronounced substrate effect at larger indentation depths.

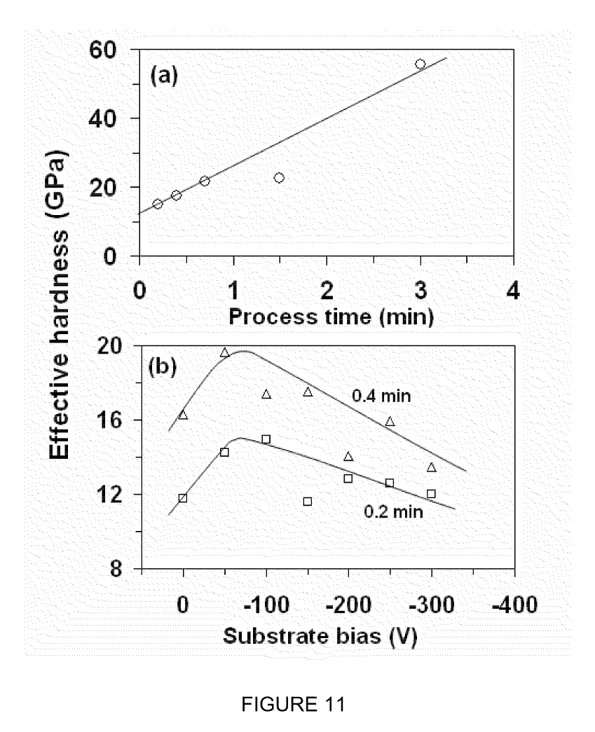

The peak of the maximum contact pressure represented the effective hardness of the processed material. The term “effective hardness” refers to the surface resistance against plastic flow and is a function of both the carbon film and substrate properties. The dependence of the effective hardness on process time and substrate bias for an FCVA process on a silicon substrate is shown in FIG. 11. For fixed ion kinetic energy (e.g. 120 eV), the effective hardness increased with the process time (see FIG. 11(a)). This trend can be attributed to the substrate effect, which becomes more significant with thinner films. For process times of 0.2 min and 0.4 min, the highest effective hardness was obtained for bias voltage between −50 V and −100 V (see FIG. 11(b)). Higher effective hardness values were produced for 0.4 min than 0.2 min process time due to the substrate effect. In addition to the substrate effect, the sp³ carbon hybridization may also affect the nanomechanical properties. In some cases, the effective hardness depends on the amount of sp³ hybridized carbon and the amount of carbon-silicon intermixing in the near-surface region. For fixed carbon ion fluence, a high sp³ fraction resulted in high effective hardness (FIG. 8 and FIG. 11). Less carbon-silicon intermixing resulted in a high carbon concentration in the near-surface region, which resulted in a high effective hardness.

### Example 2

### FCVA on a Magnetic Recording Medium

### I. Introduction

Surface modification of the magnetic recording medium of hard disks by FCVA treatment was examined. The magnetic storage layer was exposed by sputter etching the overlying carbon overcoat. Sputter etching was performed in a high-vacuum atmosphere to minimize oxidation of the underlying magnetic storage layer. The exposed magnetic storage layer was subjected to energetic C⁺ ion bombardment under conditions of zero and −100 V pulsed (25 kHz frequency) substrate bias. The effects of FCVA treatment conditions on carbon implantation profiles, carbon atom hybridization, surface roughness, and nanomechanical properties of the surface-modified hard disk magnetic recording medium was analyzed using T-DYN, XPS, AFM, and SFM.

### II. Experimental Procedures

A. Sample Preparation

Unlubricated hard disks having a diameter of 3.5 in. were cut into 10×10 mm² samples. The magnetic storage layer was composed of 61-63 atomic % Co, 12-15 atomic % Pt, 10-14 atomic % Cr, 10-15 atomic % B, and less than 2 atomic % C, Cu, and O. The hard disk samples were loaded onto a substrate stage of a FCVA system and the carbon overcoat (about 4 nm thick) was removed by Ar⁺ ion sputter etching under a working pressure of 2.4×10⁻⁴ Torr to prevent oxidation. The Ar⁺ ion etch time to completely remove the carbon overcoat was determined from simulation results of the sputter etch rate of carbon and profilometry measurements of the etch thickness of the carbon overcoat. A 64 mm Kaufman ion source (Commonwealth Scientific, Ionbeam Scientific, Berks, UK)) that produced a 500 eV Ar⁺ ion beam of constant ion flux was used for in situ sputter etching. During sputter etching and FCVA treatment, the substrate holder was rotated at 60 rpm to achieve substantially uniform surface modification.

Other experimental procedures were as described in Example 1 above.

### III. Results and Discussion

A. Sputter Etching of the Pre-Existing Carbon Overcoat

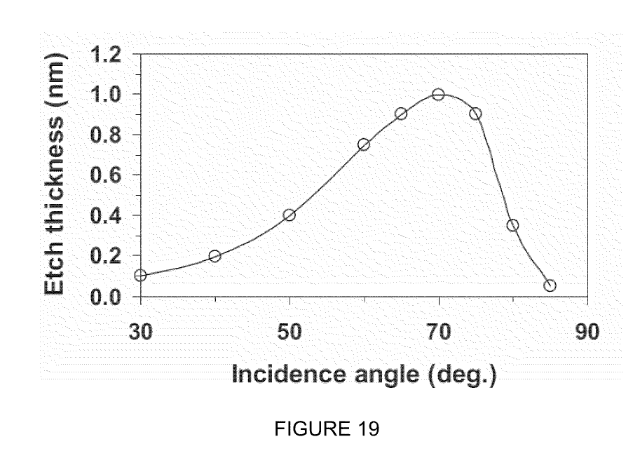

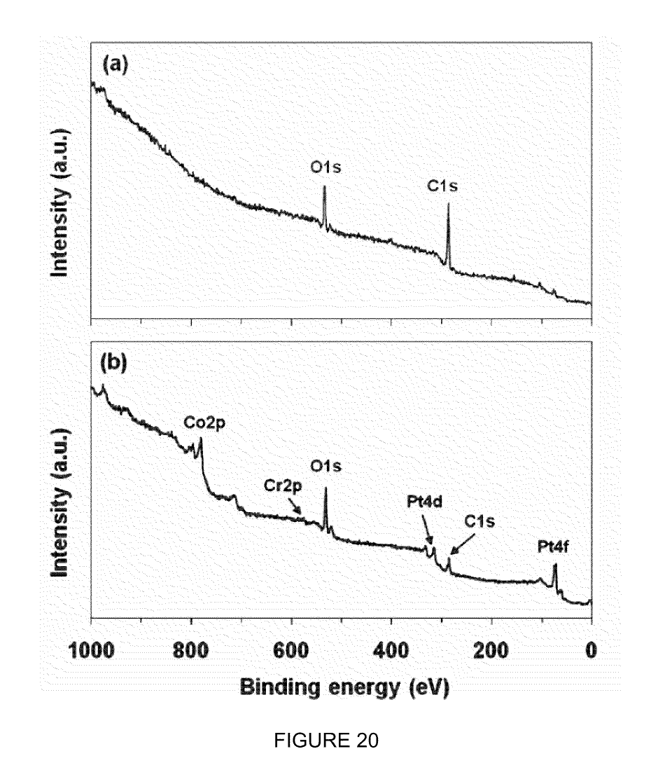

FIG. 19 shows T-DYN, simulation results of the etch thickness of carbon as a function of the Ar⁺ ion-beam incidence angle for 1×10¹⁶ ions/cm². The maximum etch thickness corresponded to an incidence angle of 70°. Therefore, to minimize the time for removing the pre-existing carbon overcoat from the hard disk samples, the incidence angle of the Ar⁺ ion beam was set at 60°. Surface profilometry and XPS measurements confirmed the removal of the 4-nm-thick carbon overcoat. For 4, 6, and 8 min of Ar⁺ ion sputtering, the measured etch thickness was equal to 3.3, 4.5, and 7.3 nm, respectively. Because the binding energy of cobalt is less than that of carbon, the etch rate increased after the removal of the carbon overcoat. XPS results showed the complete removal of the carbon overcoat after sputter etching. FIGS. 20(a) and 20(b) show XPS survey spectra obtained before and after 8 min of sputter etching of a magnetic recording medium, respectively. The O 1s peak can be attributed to the adsorption of oxygen upon the exposure of the sample to the ambient. The Co 2p, Cr 2p, Pt 4d, and Pt 4f peaks and the significantly decreased intensity of the C1 s peak in the XPS spectrum shown in FIG. 20(b) indicated the exposure of the magnetic medium due to the removal of the carbon overcoat. The low-intensity C1s peak in the XPS spectrum shown in FIG. 20(b) may also be attributed to carbon adsorbents from the ambient.

B. FCVA Treatment of the Magnetic Medium

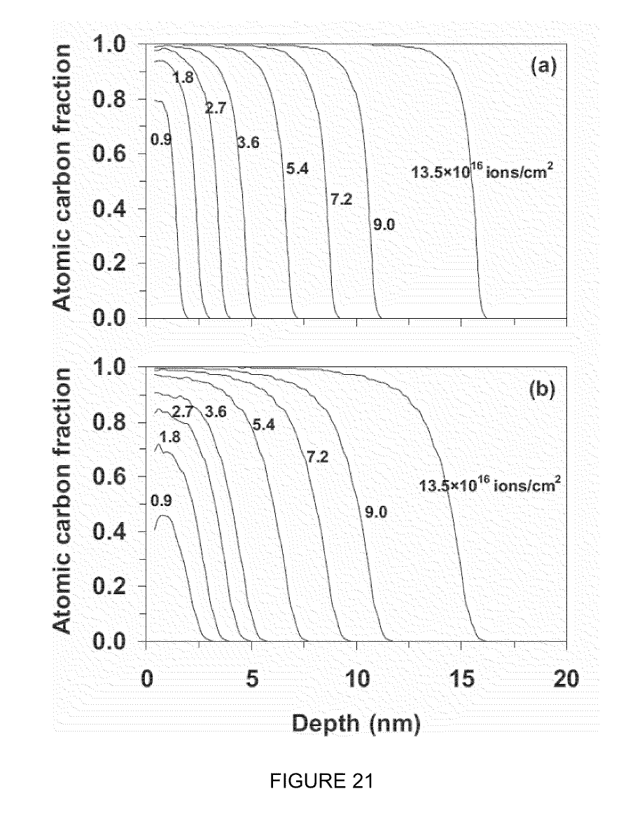

FIG. 21 shows carbon implantation profiles into a cobalt substrate, obtained from a T-DYN analysis for zero (FIGS. 21(a)) and −100 V (FIG. 21(b)) substrate bias and C⁺ ion fluence of (0.9-13.5)×10¹⁶ ions/cm² e.g., treatment time of 6-90 s. The results presented in FIG. 21, as well as in the following figures, are for a C⁺ ion flux of 1.5×10¹⁵ ions/cm²·s perpendicular to the substrate surface. The impinging ion energy was set equal to the sum of the initial ion energy (20 eV for zero substrate bias) and the ion energy due to the acceleration of the C⁺ ions through the electric sheath at the sample surface controlled by the substrate bias voltage. Substrate biasing decreased the carbon fraction at the surface and increased the thickness of the implantation profile. For a C⁺ ion fluence of 0.9×10¹⁶ ions/cm² and a substrate bias of zero or −100 V, implantation of carbon into the near-surface region of the magnetic recording medium occurred to a depth of 2 nm and 3 nm, respectively.

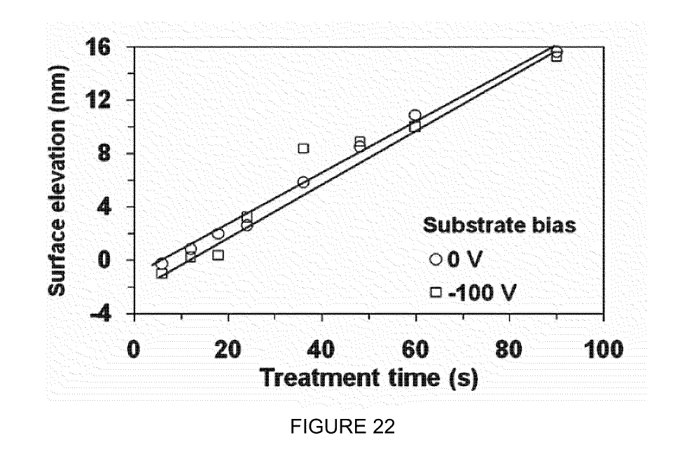

FIG. 22 shows a graph of the height difference between FCVA treated and untreated surface regions (referred to as surface elevation for brevity) as a function of treatment time for zero and −100 V substrate bias for an FCVA process on a magnetic recording medium. An etch thickness of 7.3 nm was subtracted from all the measurements shown in FIG. 22. The very small or slightly negative values obtained for short treatment time (e.g., less than 20 s) may be due to the resputtering of energetic carbon ions, especially under FCVA conditions of −100 V substrate bias.

C. Surface Chemical Composition and Oxidation Resistance

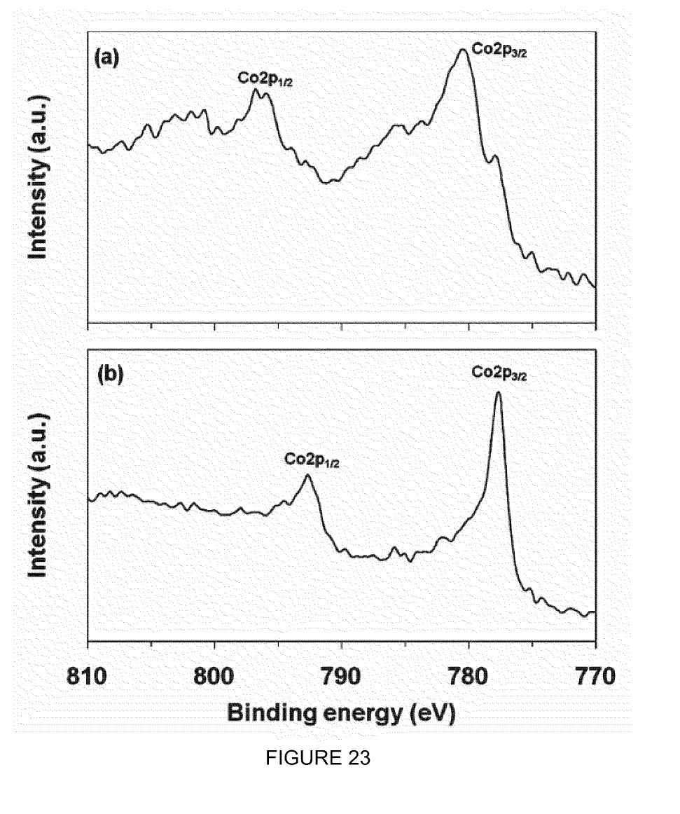

The surface chemical composition and oxidation resistance of the FCVA-treated magnetic recording medium was analyzed by XPS as shown in FIGS. 23-26. XPS window spectra of the Co 2p core-level peak obtained before and after treatment of the magnetic recording medium are shown in FIG. 23. The broad Co 2p_{3,2} peak in the spectrum of the untreated magnetic recording medium (FIG. 23(a)) indicated that cobalt exists in its oxidative state. The significantly narrower Co 2p_{3/2} peak in the spectrum of the FCVA-treated magnetic recording medium (FIG. 23(b)) indicated that FCVA treatment with C⁺ ion fluence of 0.9×10¹⁶ ions/cm² increased the oxidation resistance of the magnetic recording medium without causing a chemical reaction between carbon and cobalt. The presence of metallic cobalt after FCVA treatment (indicated by the narrow Co 2p_{3/2} peak) indicated the unchanged structure of the surface-modified magnetic recording medium.

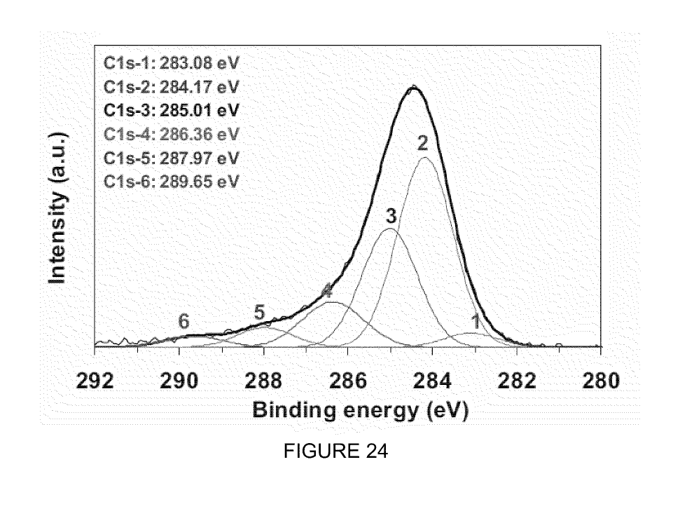

FIG. 24 shows the XPS window spectrum of the C1s peak of the FCVA-treated magnetic recording medium for a treatment time of 12 s and zero substrate bias. After inelastic background subtraction, the C1s spectrum was fitted with six Gaussian distributions at characteristic binding energies, as shown in FIG. 24. Distributions referred to as C 1 s-1, C 1s-2, and C 1s-3 correspond to sp¹, sp², and sp³ carbon hybridizations, respectively. The fraction of each type of atomic carbon bonding was estimated from the deconvolution of the C1s XPS spectrum. Distributions denoted by C 1s-4, C 1s-5, and C 1s-6 correspond to atomic carbon bonded to surface adsorbents from the ambient, hereafter referred to as satellite peaks. The sum of the satellite peak areas indicates the fraction of carbon bonding with surface adsorbents.

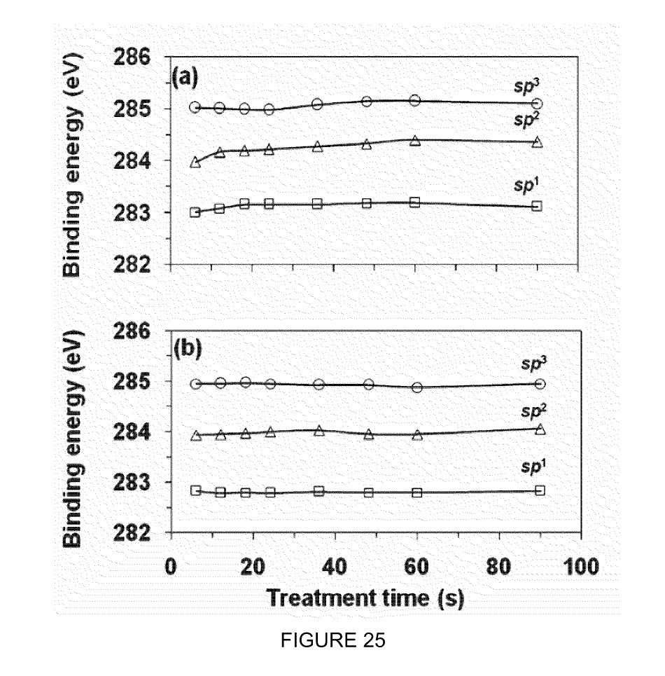

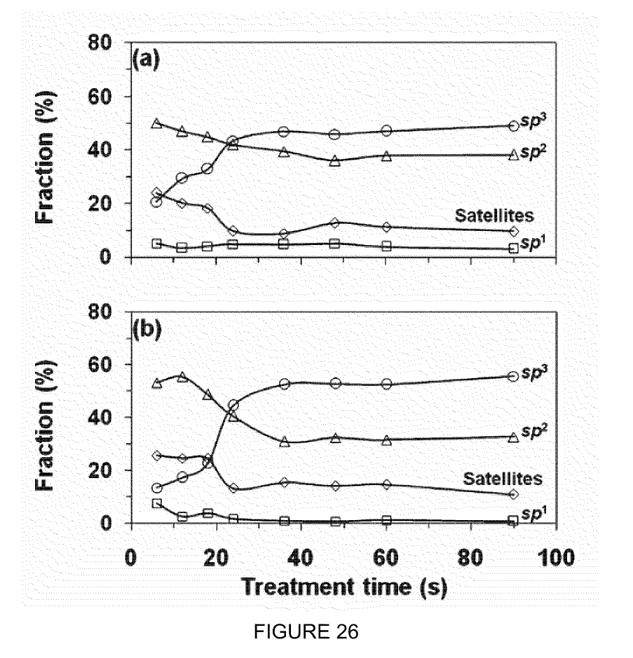

FIG. 25 shows the binding energies of sp¹, sp², and sp³ carbon hybridizations as functions of treatment time for an FCVA process on a magnetic recording medium. The relatively constant sp¹, sp², and sp³ binding energies shown in FIG. 25 indicated a constant stress in the carbon species for treatment time in the range of 6-90 s. The nanomechanical properties of the FCVA-treated magnetic medium were not affected by internal stress variations. The lower binding energies for −100 V (FIG. 25(b)) than zero (FIG. 25(a)) substrate bias may be attributed to the higher compressive stress resulting from the increased energy of impinging C⁺ ions due to the pulsed bias voltage applied to the substrate. FIG. 26 shows the dependence of sp¹, sp², sp³, and satellite fractions (atomic %) on treatment time for an FCVA process on a magnetic recording medium. For both zero (FIGS. 26(a)) and −100 V (FIG. 26(b)) substrate bias, the curves of the sp² and sp³ fractions intersected at a point corresponding to a treatment time of 24 s. The relatively low sp³ fraction for treatment time less than 20 s corresponds to shallower carbon implantation at lower treatment times. Energetic ions can penetrate the substrate to a certain depth, resulting in an increase in the density of the substrate in the near-surface region, which enhances sp³ hybridization. Thus, sp³ hybridization may be increased by the formation of a near-surface region with higher carbon fractions. Zero substrate bias yielded a higher sp³ fraction for short treatment times (e.g., 6 s). A substrate bias of −100 V resulted in higher sp³ fraction for treatment times greater than 24 s.

D. Surface Roughness

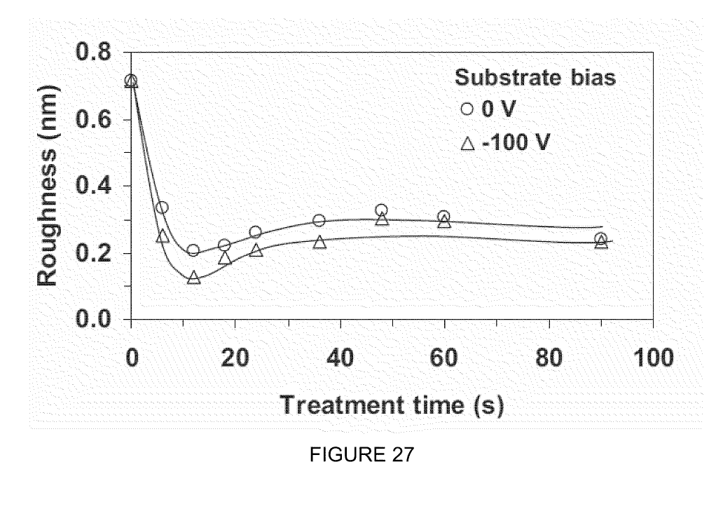

FIG. 27 shows a graph of the roughness of the magnetic recording medium as a function of treatment time. The rms roughness of the carbon-coated hard disk before Ar⁺ ion sputter etching was 0.19 nm. The roughness for zero treatment time (rms of 0.72 nm) corresponded to the magnetic recording medium surface exposed after Ar⁺ ion sputter etching for 8 min. Although Ar⁺ ion etching resulted in significant surface roughening, FCVA treatment for 12 s restored the original surface smoothness (rms of 0.2 nm). FIG. 27 also shows that a pulsed substrate bias of −100 V resulted in smoother topographies. A pulsed substrate bias may facilitate an increase in resputtering that promoted surface smoothening.

E. Nanomechanical Properties

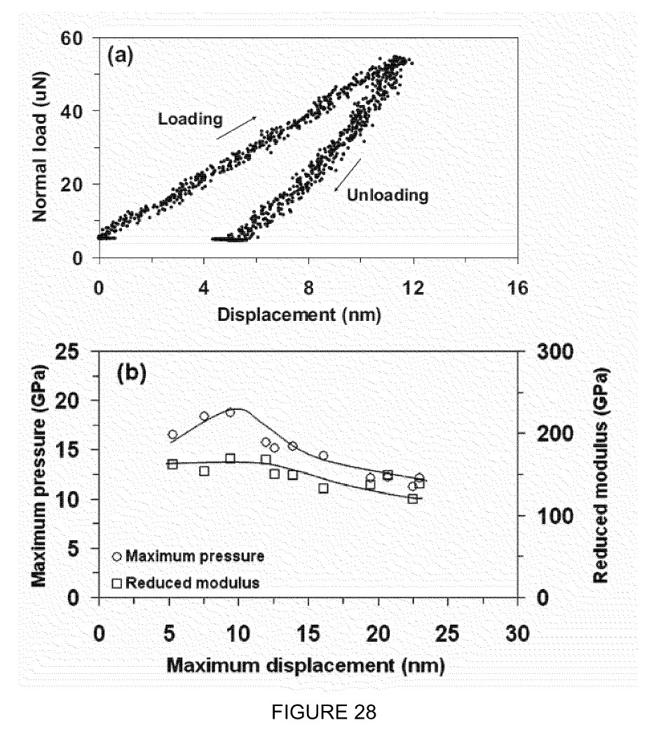

FIG. 28 shows graphs of the nanomechanical properties of the FCVA-modified magnetic recording medium for 48 s treatment time and zero substrate bias. Nanoindentation load-displacement responses, shown in FIG. 28(a), were used to determine the maximum (contact) pressure and reduced modulus, shown as functions of maximum tip displacement in FIG. 28(b). The peak value of the maximum contact pressure is the effective hardness, which indicates the material resistance to plastic deformation due to indentation. The maximum displacement corresponding to the effective hardness is referred to as the critical depth. As shown in FIG. 28(b), the reduced modulus decreased slightly as the maximum displacement increased above the critical depth.

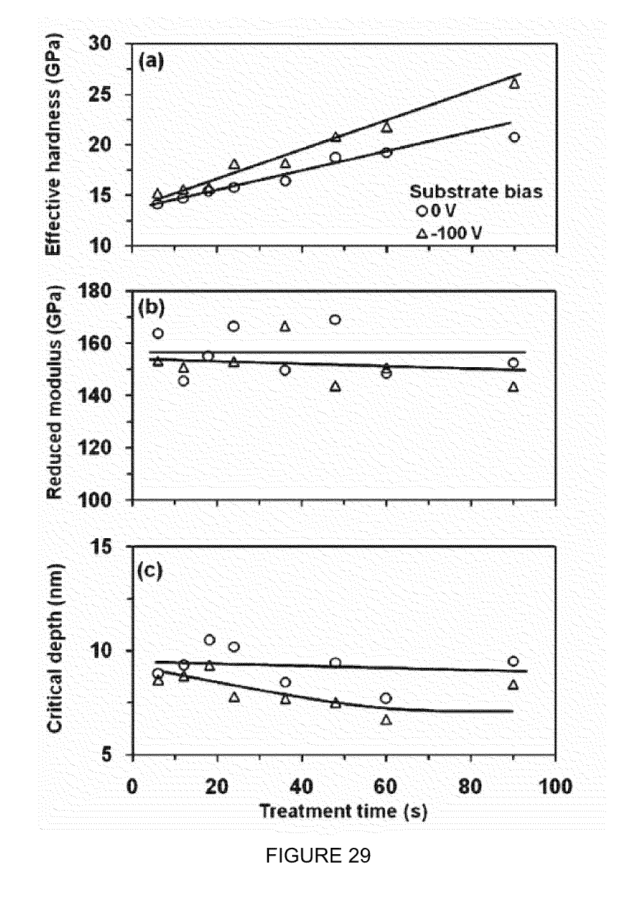

FIG. 29 shows graphs of the nanomechanical properties of the FCVA-treated magnetic recording medium for zero and −100 V substrate bias. The effective nanomechanical properties for short treatment time (e.g., low ion dose) are close to those of the unmodified magnetic recording medium, which can be estimated by extrapolating the regression lines shown in FIGS. 29(a) and 29(b) to zero treatment time. As the treatment time increased, the effective hardness increased (FIG. 29(a)), which may be due to the larger amount of implanted carbon that increased the surface deformation resistance of the magnetic recording medium. The higher hardness for −100 V pulsed substrate bias may be due to the higher sp³ content (FIG. 26(b)), resulting from the more intense bombardment by energetic C⁺ ions and the increase in surface densification. An increase in surface densification resulted in a smaller critical depth for −100 V pulsed substrate bias (FIG. 29(c)) and increased the penetration resistance of the magnetic recording medium.

### Additional Examples

Additional examples are presented below.

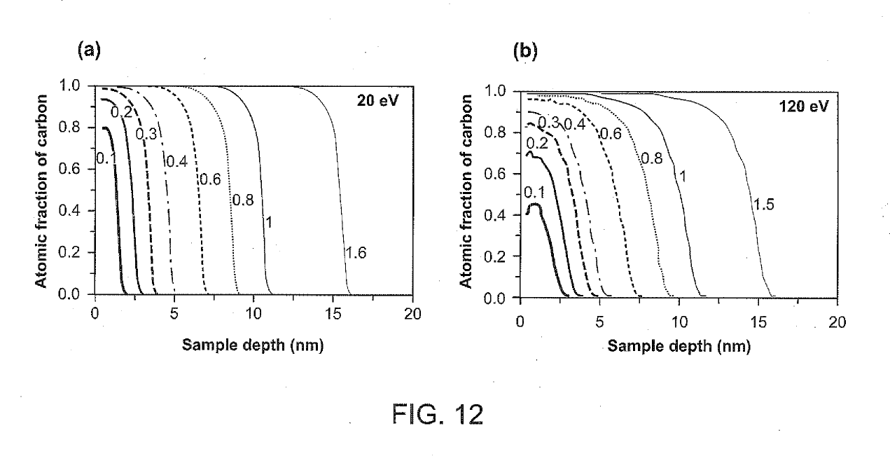

FIG. 12 shows T-DYN simulation of depth profiles for 20 eV and 120 eV ion kinetic energies, which correspond to 0 V and −100 V pulse bias, respectively, for an FCVA process on a magnetic recording medium. Each curve is labeled by its corresponding deposition time (min). The carbon ion fluence was calculated by multiplying the deposition time with the FCVA carbon ion flux (e.g., 1.48×10¹⁹ ions/m²·s). The zero substrate bias resulted in a smaller implantation depth in the magnetic layer.

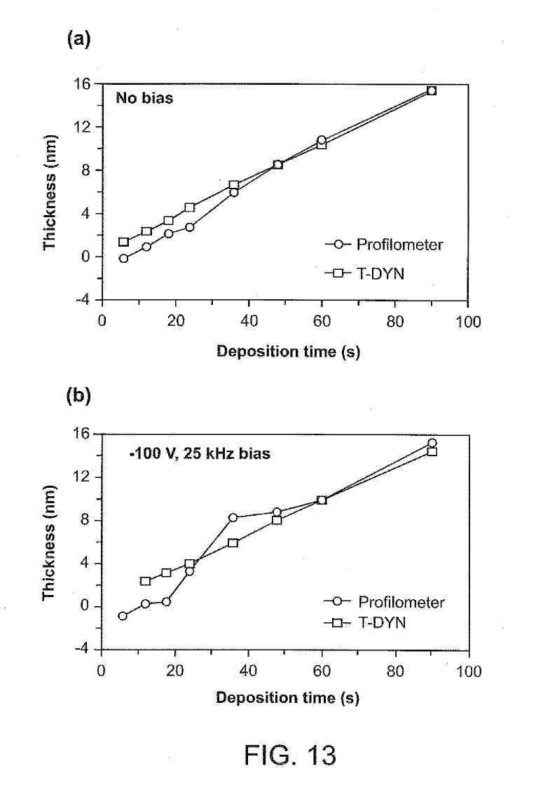

FIG. 13 shows film thickness vs. deposition time for 0 V and −100 V pulsed substrate bias for an FCVA process on a magnetic recording medium. The T-DYN simulated thickness agreed with the measured thickness. Carbon ion bombardment may have led to material removal, resulting in reduced film thickness, especially for short deposition times. The T-DYN simulation results were used to determine the thickness of the thinner films.

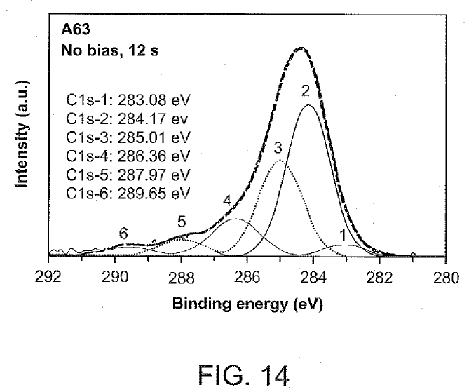

FIG. 14 shows a graph of XPS spectrum of the C1s core level peak for an FCVA process on a magnetic recording medium. Six Gaussian distributions were fitted to each XPS spectrum after performing Shirley background subtraction. C1s-1 corresponds to sp¹ content, C1s-2 corresponds to sp² content, C1s-3 corresponds to sp³ content, and C1s-4, C1s-5, and C1s-6 correspond to satellite peaks due to adsorbents. The sp³/sp² ratio was calculated using the following formula: sp³/sp² ratio=Area (C1s-3)/Area (C1s-2).

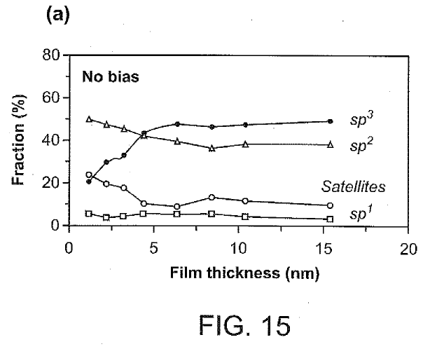

FIG. 15 shows carbon bonding vs. film thickness for an FCVA process on a magnetic recording medium. The sp¹, sp², and sp³ energy levels were relatively independent of film thickness. The bonding fractions reached a steady state after 36 s deposition (e.g., 4 nm thick carbon film). High sp², high satellite peaks and low sp³ were observed for carbon films greater than 4 nm thick. Ultrathin carbon films exhibited a different growth mechanism than thick films.

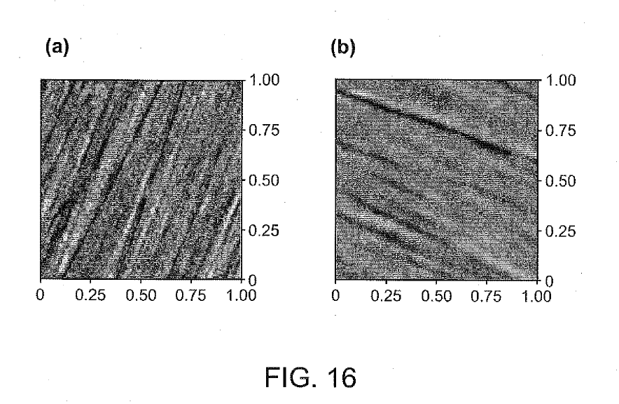

FIG. 16 shows AFM scans (1×μm²) showing surface morphology of FCVA carbon films on a magnetic recording medium. The film surfaces contained numerous parallel grooves existing on the magnetic layer. Carbon film deposition showed a surface smoothening effect.

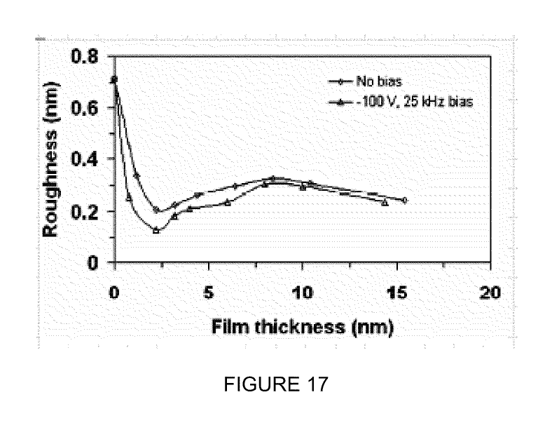

FIG. 17 shows film roughness vs. thickness depicted in a graph of rms roughness by AFM scans (1×μm²) for an FCVA-treated a magnetic recording medium. The carbon ion flux had a smoothening effect on the sputter-etched surface. For film thickness greater than 4 nm, carbon-carbon collisions dominated. Carbon ions of high energy induced more diffusion and/or sputter-etching, thus, they were more effective in surface smoothening. sp³ hybridized carbon was more sputter-resistant than sp² hybridized carbon.

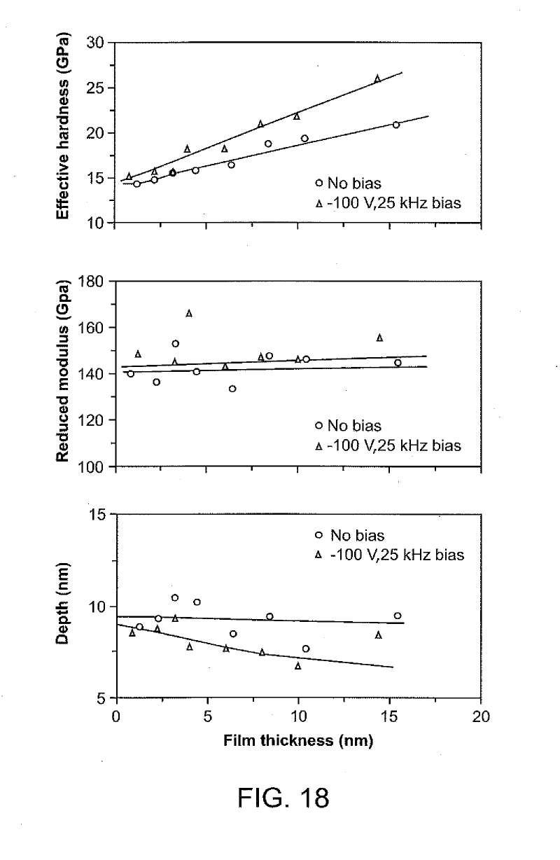

FIG. 18 shows mechanical properties measured from nanoindentation for an FCVA-treated a magnetic recording medium. Nanoindentations were performed with a cubic diamond tip of 75 nm radius. The effective hardness was the maximum pressure obtained in a series of nanoindentations of varying depth. The reduced modulus was the average in a series of nanoindentations. The depth values corresponded to where the effective hardness was acquired. Substrate biased deposition yielded better quality films than zero substrate bias in the thick-film region.

Although the foregoing invention has been described in some detail by way of illustration and example for purposes of clarity of understanding, it is readily apparent to those of ordinary skill in the art in light of the teachings of this invention that certain changes and modifications may be made thereto without departing from the spirit or scope of the appended claims. It is also to be understood that the terminology used herein is for the purpose of describing particular embodiments only, and is not intended to be limiting, since the scope of the present invention will be limited only by the appended claims.

Accordingly, the preceding merely illustrates the principles of the invention. It will be appreciated that those skilled in the art will be able to devise various arrangements which, although not explicitly described or shown herein, embody the principles of the invention and are included within its spirit and scope. Furthermore, all examples and conditional language recited herein are principally intended to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention as well as specific examples thereof, are intended to encompass both structural and functional equivalents thereof. Additionally, it is intended that such equivalents include both currently known equivalents and equivalents developed in the future, e.g., any elements developed that perform the same function, regardless of structure. The scope of the present invention, therefore, is not intended to be limited to the exemplary embodiments shown and described herein. Rather, the scope and spirit of present invention is embodied by the appended claims.

1. A cathodic arc system comprising:
an arc source;
a cathode magnetic field source;
an upstream magnetic field source;
a substrate holder; and
a plasma conduit in communication with the arc source and the substrate holder,
wherein the system is configured to stabilize a dc arc discharge plasma from the arc source.

2. The system of claim 1, wherein the cathode magnetic field and the upstream magnetic field sources produce opposite magnetic fields.

3. The system of claim 1, wherein the cathode magnetic field and the upstream magnetic field sources are configured to produce a combined magnetic field having a magnetic field intensity ranging from 30 mT to 40 mT at a surface of the arc source.

4. The system of claim 1, wherein the cathode magnetic field source is a cathode magnetic coil.

5. The system of claim 4, wherein the cathode magnetic coil has a current ranging from 25 A to 35 A, and is configured to produce a magnetic field intensity from 30 mT to 150 mT.

6. The system of claim 1, wherein the upstream magnetic field source is an upstream magnetic coil.

7. The system of claim 6, wherein the upstream magnetic coil has a current ranging from 25 A to 35 A, and is configured to produce a magnetic field intensity from 10 mT to 100 mT.

8. The system of claim 1, wherein the system is configured to direct the plasma through the plasma conduit and filter the plasma.

9. The system of claim 8, wherein the arc source and the substrate holder are in a three-dimensional out-of-plane configuration.

10. The system of claim 9, further comprising a downstream magnetic field source.

11-18. (canceled)

19. A method of modifying a surface of a substrate with a material, the method comprising:
producing a plasma from an arc source;
generating a combined magnetic field from a cathode magnetic field source and an upstream magnetic field source to obtain at least one of a stabilized plasma and a filtered plasma; and
contacting the plasma with a surface of a substrate to modify the surface of the substrate with the material.

20. The method of claim 19, wherein the cathode magnetic field and the upstream magnetic field sources produce opposite magnetic fields.

21. The method of claim 19, wherein the contacting comprises implanting the material into the surface of the substrate.

22. The method of claim 19, wherein the contacting comprises depositing the material onto the surface of the substrate.

23. The method of claim 19, wherein the combined magnetic field has an intensity ranging from 10 mT to 50 mT

24. The method of claim 19, wherein the material comprises a cathode material.

25. The method of claim 19, further comprising directing the plasma through a plasma conduit, wherein the plasma conduit is configured in a three-dimensional out-of-plane configuration.

26-33. (canceled)

34. A magnetic recording medium comprising:
a substrate layer;
a magnetic storage layer comprising a magnetic storage material; and
a thin near-surface layer comprising the magnetic storage material and a cathode material.

35. The magnetic recording medium of claim 34, wherein the thin near-surface layer has a thickness of 10 nm or less.

36-39. (canceled)
